(19) United States
(12) Patent Application Publication
(10) Pub. No.: US 2024/0244341 A1
(43) Pub. Date: Jul. 18, 2024

(54) IMAGE SENSOR INCLUDING COLOR SEPARATING LENS ARRAY AND ELECTRONIC DEVICE INCLUDING THE SAME

(71) Applicant: SAMSUNG ELECTRONICS CO., LTD., Suwon-si (KR)

(72) Inventors: Seokho YUN, Suwon-si (KR); Sookyoung Roh, Suwon-si (KR); Choonlae Cho, Suwon-si (KR)

(73) Assignee: SAMSUNG ELECTRONICS CO., LTD., Suwon-si (KR)

(21) Appl. No.: 18/415,399

(22) Filed: Jan. 17, 2024

(30) Foreign Application Priority Data
Jan. 17, 2023 (KR) 10-2023-0006981
Mar. 3, 2023 (KR) 10-2023-0028749

(51) Int. Cl. H04N 25/13; G02B 27/10; G02B 27/12; H04N 25/77

(52) U.S. Cl. CPC H04N 25/135; G02B 27/1013; G02B 27/123; H04N 25/77

(57) ABSTRACT

An image sensor includes: a sensor substrate including a first pixel and a second pixel that are each configured to sense light of a first wavelength, and a third pixel and a fourth pixel that are each configured to sense light of a second wavelength; and a color separating lens array (CSLA) provided on the sensor substrate, the CSLA being configured to separate incident light according to wavelength and condense the separated incident light onto the first pixel, the second pixel, the third pixel, and the fourth pixel. The first pixel, the second pixel, the third pixel, and the fourth pixel are provided in a 2×2 arrangement. The light of the first wavelength and the light of the second wavelength have a complementary color relationship.

### CROSS-REFERENCE TO RELATED APPLICATION

This application is based on and claims priority under 35 U.S.C. § 119 to Korean Patent Application Nos. 10-2023-0006981, filed on Jan. 17, 2023, and 10-2023-0028749, filed on Mar. 3, 2023, in the Korean Intellectual Property Office, the disclosures of which are incorporated by reference herein in their entireties.

### FIELD

The disclosed embodiments relate to an image sensor and an electronic device including the image sensor, and more particularly, to an image sensor including a color separating lens array (CSLA) and an electronic device including the same.

### BACKGROUND

The number of pixels of image sensors has been gradually increased, and accordingly, pixel miniaturization is desirable. For pixel miniaturization, securing an amount of light and removing noise are important issues.

Image sensors generally display images of various colors or sense a color of incident light by using a color filter. However, because the color filter absorbs light of a color other than light of the corresponding color, a light utilization efficiency of the image sensor may be reduced. For example, when an RGB color filter is used, because only ⅓ of incident light is transmitted and the remaining ⅔ of the incident light is absorbed, the light utilization efficiency of the image sensor is only about 33%, and a light loss is very large.

Recently, attempts have been made to use a color separating lens array (CSLA) in order to improve light utilization efficiency of the image sensor. The CSLA may separate the color of incident light by using diffraction or refraction characteristics of light varying depending on a wavelength, and adjust a directionality for each wavelength according to a refractive index and a shape. Colors separated by the CSLA may be transferred to respective corresponding pixels.

### SUMMARY

Described below is an image sensor having improved light utilization efficiency by using a color separating lens array (CSLA).

Described below is an electronic device including an image sensor having improved light utilization efficiency.

Additional aspects will be set forth in part in the description which follows and, in part, will be apparent from the description, or may be learned by practice of the presented embodiments.

An image sensor may include: a sensor substrate including a first pixel and a second pixel that are each configured to sense light of a first wavelength, and a third pixel and a fourth pixel that are each configured to sense light of a second wavelength; and a color separating lens array (CSLA) provided on the sensor substrate, the CSLA being configured to separate incident light according to wavelength and condense the separated incident light onto the first pixel, the second pixel, the third pixel, and the fourth pixel. The first pixel, the second pixel, the third pixel, and the fourth pixel may be provided in a 2×2 arrangement. The first pixel and the second pixel may be provided to be oriented diagonal to each other. The third pixel and the fourth pixel may be provided to be oriented diagonal to each other. The first pixel and the third pixel may be provided to be oriented in a first direction with respect to each other. The first pixel and the fourth pixel may be provided to be oriented in a second direction with respect to each other, the second direction being perpendicular to the first direction. The CSLA may include a first pixel corresponding region that is provided on the first pixel, a second pixel corresponding region that is provided on the second pixel, a third pixel corresponding region that is provided on the third pixel, and a fourth pixel corresponding region that is provided on the fourth pixel. Each of the first pixel corresponding region, the second pixel corresponding region, the third pixel corresponding region, and the fourth pixel corresponding region may include a plurality of nanoposts. The plurality of nanoposts may be configured such that color separation occurs only within the 2×2 arrangement. The light of the first wavelength and the light of the second wavelength may have a complementary color relationship.

The plurality of nanoposts may be further configured such that the color separation occurs between pixels adjacent in the second direction among the first pixel, the second pixel, the third pixel, and the fourth pixel.

The plurality of nanoposts may be further configured such that the color separation occurs between pixels adjacent in the first direction and pixels adjacent in the second direction among the first pixel, the second pixel, the third pixel, and the fourth pixel.

The plurality of nanoposts may be arranged asymmetrically with respect to (i) a line extending in the first direction from a center of each of the first pixel corresponding region, the second pixel corresponding region, the third pixel corresponding region, and the fourth pixel corresponding region and (ii) a line extending in the second direction from the center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

The plurality of nanoposts may be arranged asymmetrically with respect to a line extending in the first direction from a center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

The plurality of nanoposts may be arranged symmetrically with respect to a line extending in the second direction from a center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

The light of the first wavelength may be red light, and the light of the second wavelength may be cyan light.

The light of the first wavelength may be green light, and the light of the second wavelength may be magenta light.

The light of the first wavelength may be blue light, and the light of the second wavelength may be yellow light.

The sensor substrate may further include: a fifth pixel and a sixth pixel that are each configured to sense light of a third wavelength, a seventh pixel and an eighth pixel that are each configured to sense light of a fourth wavelength, a ninth pixel and a tenth pixel that are each configured to sense light of a fifth wavelength, an eleventh pixel and a twelfth pixel that are each configured to sense light of a sixth wavelength, a thirteenth pixel and a fourteenth pixel that are each configured to sense the light of the first wavelength, and a fifteenth pixel and a sixteenth pixel that are each configured to sense the light of the second wavelength. The fifth pixel, the sixth pixel, the seventh pixel, and the eighth pixel may be provided in the 2×2 arrangement. The fifth pixel and the sixth pixel may be provided are provided to be oriented diagonal to each other. The seventh pixel and the eighth pixel may be provided to be oriented diagonal to each other. The fifth pixel and the seventh pixel may be provided to be oriented in the first direction with respect to each other. The fifth pixel and the eighth pixel may be provided to be oriented in the second direction with respect to each other. The ninth pixel, the tenth pixel, the eleventh pixel, and the twelfth pixel may be provided in the 2×2 arrangement. The ninth pixel and the tenth pixel may be provided to be oriented diagonal to each other. The eleventh pixel and the twelfth pixel may be provided to be oriented diagonal to each other. The ninth pixel and the eleventh pixel may be provided to be oriented in the first direction with respect to each other. The ninth pixel and the twelfth pixel may be provided to be oriented in the second direction with respect to each other. The thirteenth pixel, the fourteenth pixel, the fifteenth pixel, and the sixteenth pixel may be provided in the 2×2 arrangement. The thirteenth pixel and the fourteenth pixel may be provided to be oriented diagonal to each other. The fifteen pixel and the sixteenth pixels may be provided to be oriented diagonal to each other. The thirteenth pixel and the fifteenth pixel may be provided to be oriented in the first direction with respect to each other. The thirteenth pixel and the sixteenth pixel may be provided to be oriented in the second direction with respect to each other. The first pixel, the second pixel, the third pixel, the fourth pixel, the fifth pixel, the sixth pixel, the seventh pixel, the eighth pixel, the ninth pixel, the tenth pixel, the eleventh pixel, the twelfth pixel, the thirteenth pixel, the fourteenth pixel, the fifteenth pixel, and the sixteenth pixel may be provided in a 4×4 arrangement.

The light of the first wavelength may be green light, the light of the second wavelength may be magenta light, the light of the third wavelength may be red light, the light of the fourth wavelength may be cyan light, the light of the fifth wavelength may be blue light, and the light of the sixth wavelength may be yellow light.

The image sensor may further include: a flat lens surrounding the first pixel, the second pixel, the third pixel, and the fourth pixel in the 2×2 arrangement on the CSLA.

At least one of the first pixel, the second pixel, the third pixel, or the fourth pixel may include a plurality of sub-pixels.

The plurality of sub-pixels may be configured to be used for autofocusing.

An electronic apparatus may include: a lens assembly including one or more lenses, the lens assembly being configured to form an optical image of a subject; an image sensor configured to generate an electrical signal based on the optical image formed by the lens assembly; and a processor configured to process the electrical signal generated by the image sensor. The image sensor may include: a sensor substrate including a first pixel and a second pixel that are each configured to sense light of a first wavelength, and a third pixel and a fourth pixel that are each configured to sense light of a second wavelength; and a color separating lens array (CSLA) provided on the sensor substrate, the CSLA being configured to separate incident light according to wavelength and condense the separated incident light onto the first pixel, the second pixel, the third pixel, and the fourth pixel. The first pixel, the second pixel, the third pixel, and the fourth pixel may be provided in a 2×2 arrangement. The first pixel and the second pixel may be provided to be oriented diagonal to each other. The third pixel and the fourth pixel may be provided to be oriented diagonal to each other. The first pixel and the third pixel may be provided to be oriented in a first direction with respect to each other. The first pixel and the fourth pixel may be provided to be oriented in a second direction with respect to each other, the second direction being perpendicular to the first direction. The CSLA may include a first pixel corresponding region that is provided on the first pixel, a second pixel corresponding region that is provided on the second pixel, a third pixel corresponding region that is provided on the third pixel, and a fourth pixel corresponding region that is provided on the fourth pixel. Each of the first pixel corresponding region, the second pixel corresponding region, the third pixel corresponding region, and the fourth pixel corresponding region may include a plurality of nanoposts. The plurality of nanoposts may be configured such that color separation occurs only within the 2×2 arrangement. The light of the first wavelength and the light of the second wavelength may have a complementary color relationship.

The plurality of nanoposts may be further configured such that the color separation occurs between pixels adjacent in the second direction among the first pixel, the second pixel, the third pixel, and the fourth pixel.

The plurality of nanoposts may be further configured such that the color separation occurs between pixels adjacent in the first direction and pixels adjacent in the second direction among the first pixel, the second pixel, the third pixel, and the fourth pixel.

The sensor substrate may further include: a fifth pixel and a sixth pixel that are each configured to sense light of a third wavelength, a seventh pixel and an eighth pixel that are each configured to sense light of a fourth wavelength, a ninth pixel and a tenth pixel that are each configured to sense light of a fifth wavelength, an eleventh pixel and a twelfth pixel that are each configured to sense light of a sixth wavelength, a thirteenth pixel and a fourteenth pixel that are each configured to sense the light of the first wavelength, and a fifteenth pixel and a sixteenth pixel that are each configured to sense the light of the second wavelength. The fifth pixel, the sixth pixel, the seventh pixel, and the eighth pixel may be provided in the 2×2 arrangement. The fifth pixel and the sixth pixel may be provided are provided to be oriented diagonal to each other. The seventh pixel and the eighth pixel may be provided to be oriented diagonal to each other. The fifth pixel and the seventh pixel may be provided to be oriented in the first direction with respect to each other. The fifth pixel and the eighth pixel may be provided to be oriented in the second direction with respect to each other. The ninth pixel, the tenth pixel, the eleventh pixel, and the twelfth pixel may be provided in the 2×2 arrangement. The ninth pixel and the tenth pixel may be provided to be oriented diagonal to each other. The eleventh pixel and the twelfth pixel may be provided to be oriented diagonal to each other. The ninth pixel and the eleventh pixel may be provided to be oriented in the first direction with respect to each other. The ninth pixel and the twelfth pixel may be provided to be oriented in the second direction with respect to each other. The thirteenth pixel, the fourteenth pixel, the fifteenth pixel, and the sixteenth pixel may be provided in the 2×2 arrangement. The thirteenth pixel and the fourteenth pixel may be provided to be oriented diagonal to each other. The fifteen pixel and the sixteenth pixels may be provided to be oriented diagonal to each other. The thirteenth pixel and the fifteenth pixel may be provided to be oriented in the first direction with respect to each other. The thirteenth pixel and the sixteenth pixel may be provided to be oriented in the second direction with respect to each other. The first pixel, the second pixel, the third pixel, the fourth pixel, the fifth pixel, the sixth pixel, the seventh pixel, the eighth pixel, the ninth pixel, the tenth pixel, the eleventh pixel, the twelfth pixel, the thirteenth pixel, the fourteenth pixel, the fifteenth pixel, and the sixteenth pixel may be provided in a 4×4 arrangement.

The light of the first wavelength may be green light, the light of the second wavelength may be magenta light, the light of the third wavelength may be red light, the light of the fourth wavelength may be cyan light, the light of the fifth wavelength may be blue light, and the light of the sixth wavelength may be yellow light.

At least one of the first pixel, the second pixel, the third pixel, or the fourth pixel may include a plurality of sub-pixels. The plurality of sub-pixels may be configured to be used for autofocusing.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of an image sensor;

FIG. 2 is a diagram illustrating a pixel array of an image sensor including a color separating lens array (CSLA) according to an embodiment;

FIG. 3A is a diagram schematically illustrating a cross section of the image sensor of FIG. 2 in a first direction, and FIG. 3B is a diagram schematically illustrating a cross section of the image sensor of FIG. 2 in a second direction;

FIG. 4 is a diagram schematically illustrating a cross section of the CSLA of FIG. 2;

FIG. 5 is a diagram illustrating a pixel array of an image sensor including a CSLA according to an embodiment;

FIG. 6A is a diagram schematically illustrating a cross section of the image sensor of FIG. 5 in a first direction, and FIG. 6B is a diagram schematically illustrating a cross section of the image sensor of FIG. 5 in a second direction;

FIG. 7 is a diagram schematically illustrating a cross section of the CSLA of FIG. 5;

FIG. 8 is a diagram illustrating a pixel array of an image sensor including a CSLA according to an embodiment;

FIG. 9 is a diagram schematically illustrating a cross section of the CSLA of FIG. 8;

FIG. 10 is a diagram illustrating a pixel array of an image sensor including a CSLA according to an embodiment;

FIG. 11A is a diagram schematically illustrating a cross section of the image sensor of FIG. 10 in a first direction, and FIG. 11B is a diagram schematically illustrating a cross section of the image sensor of FIG. 10 in a second direction;

FIG. 12 is a diagram illustrating a pixel array of an image sensor including a CSLA according to an embodiment ;

FIG. 13A is a diagram schematically illustrating a cross section of the image sensor of FIG. 12 in a first direction, and FIG. 13B is a diagram schematically illustrating a cross section of the image sensor of FIG. 12 in a second direction;

FIG. 14 is a diagram conceptually illustrating a pixel arrangement of a sensor substrate according to an embodiment;

FIG. 15 is a diagram conceptually illustrating another embodiment of a pixel arrangement of a sensor substrate;

FIGS. 16A to 16G are diagrams conceptually illustrating a pixel array constituting a unit pixel arrangement;

FIG. 17 is a block diagram of an electronic device including an image sensor according to an embodiment; and

FIG. 18 is a block diagram of a camera module included in the electronic device of FIG. 17 according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, an image sensor including a color separating lens array (CSLA) and an electronic device including the same will be described in detail with reference to accompanying drawings. The embodiments are capable of various modifications and may be embodied in many different forms. In the drawings, like reference numerals denote like components, and sizes of components in the drawings may be exaggerated for convenience of explanation.

When a layer, a film, a region, or a panel is referred to as being “on” another element, it may be directly on/under/at left/right sides of the other layer or substrate, or intervening layers may also be present.

It will be understood that although the terms “first,” “second,” etc. may be used herein to describe various components, these components should not be limited by these terms. These components are only used to distinguish one component from another. These terms do not limit that materials or structures of components are different from one another.

An expression used in the singular encompasses the expression of the plural, unless it has a clearly different meaning in the context. It will be further understood that when a portion is referred to as “comprises” another component, the portion may not exclude another component but may further comprise another component unless the context states otherwise.

In addition, the terms such as “ . . . unit”, “module”, etc. provided herein indicates a unit performing a function or operation, and may be realized by hardware, software, or a combination of hardware and software.

The use of the terms of “the above-described” and similar indicative terms may correspond to both the singular forms and the plural forms. Also, the use of all exemplary terms (for example, etc.) is only to describe a technical spirit in detail, and the scope of rights is not limited by these terms unless the context is limited by the claims.

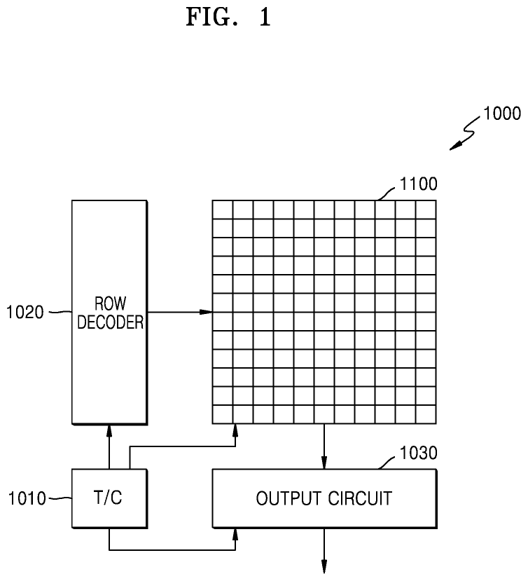

FIG. 1 is a schematic block diagram of an image sensor.

Referring to FIG. 1, the image sensor 1000 may include a pixel array 1100, a timing controller 1010, a row decoder 1020, and an output circuit 1030. The image sensor 1000 may include a charge coupled device (CCD) image sensor or a complementary metal oxide semiconductor (CMOS) image sensor.

The pixel array 1100 includes pixels that are two-dimensionally arranged in a plurality of rows and columns. The row decoder 1020 selects one of the rows in the pixel array 1100 in response to a row address signal output from the timing controller 1010. The output circuit 1030 outputs a photosensitive signal, in a column unit, from a plurality of pixels arranged in the selected row. To this end, the output circuit 1030 may include a column decoder and an analog-to-digital converter (ADC). For example, the output circuit 1030 may include a column decoder and a plurality of ADCs arranged respectively for the columns in the pixel array 1100 or one ADC arranged at an output end of a column decoder. The timing controller 1010, the row decoder 1020, and the output circuit 1030 maybe implemented as one chip or in separate chips. A processor for processing an image signal output from the output circuit 1030 maybe implemented as one chip with the timing controller 1010, the row decoder 1020, and the output circuit 1030.

The pixel array 1100 of the image sensor 1000 may include a CSLA that condenses light of a color corresponding to a specific pixel.

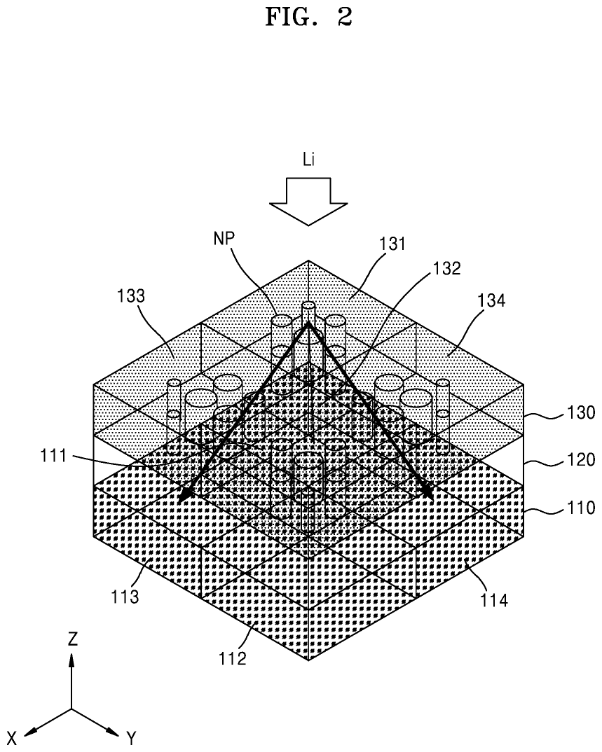

FIG. 2 is a diagram illustrating a pixel array of an image sensor including a CSLA 130 according to an embodiment.

Referring to FIG. 2, the pixel array of the image sensor may include a sensor substrate 110 including a plurality of pixels 111, 112, 113, and 114 sensing light, and the CSLA 130 on the sensor substrate 110. A spacer layer 120 may be provided between the sensor substrate 110 and the CSLA 130.

The sensor substrate 110 may include the plurality of pixels 111, 112, 113, and 114 that convert light into electrical signals. This region division is for sensing incident light by a unit pattern. For example, the first pixel 111 and the second pixel 112 may sense light having a first wavelength, and the third pixel 113 and the fourth pixel 114 may sense light having a second wavelength. The plurality of pixels 111, 112, 113, and 114 may be two-dimensionally arranged in a first direction (X direction) and a second direction (Y direction). The second direction may form a right angle with respect to the first direction. The first pixel 111, the second pixel 112, the third pixel 113, and the fourth pixel 114 may be provided in a 2×2 arrangement. The first pixel 111 and the third pixel 113 may be arranged in the first direction (X direction), and the first pixel 111 and the fourth pixel 114 may be arranged in the second direction (Y direction). The first pixel 111 and the second pixel 112 may be arranged in a diagonal direction, and the third pixel 113 and the fourth pixel 114 may be arranged in the diagonal direction. Light of a first wavelength may have a complementary color relationship with light of a second wavelength. For example, the light of the first wavelength may be red light, and the light of the second wavelength may be cyan light. Alternatively, the light of the first wavelength may be green light, and the light of the second wavelength may be magenta light. Alternatively, the light of the first wavelength may be blue light, and the light of the second wavelength may be yellow light.

Hereinafter, a diagonal arrangement may refer to an arrangement in which, for example, as described above, the first pixel 111 and the third pixel 113 are arranged in the first direction (X direction), the first pixel 111 and the fourth pixel 114 are arranged in the second direction (Y direction), the second pixel 112 sensing the light of the first wavelength is provided in the diagonal direction between the first direction (X direction) and the second direction (Y direction) of the first pixel 111 sensing the light of the first wavelength, and the fourth pixel 114 sensing the light of the second wavelength is provided in the diagonal direction between a direction opposite to the first direction (X direction) and the second direction (Y direction) of the third pixel 113 sensing the light of the second wavelength. The 2×2 arrangement described above may be referred to as a unit pixel arrangement. In FIG. 2, the first pixel 111, the second pixel 112, the third pixel 113, and the fourth pixel 114 are shown one by one as an example, but a plurality of pixels may be provided in various arrangements.

The spacer layer 120 may maintain a gap between the sensor substrate 110 and the CSLA 130 to be constant, and secure a focal length of the CSLA 130.

The CSLA 130 may be provided on the spacer layer 120, and divided in various ways. For example, the CSLA 130 may be divided into a first pixel corresponding region 131 corresponding to the first pixel 111, a second pixel corresponding region 132 corresponding to the second pixel 112, a third pixel corresponding region 132 corresponding to the corresponding to the third pixel 113, and a fourth pixel corresponding region 134 corresponding to the fourth pixel 114. For example, the first pixel corresponding region 131 may correspond to the first pixel 111 and may be provided on the first pixel 111, and the second pixel corresponding region 132 may correspond to the second pixel 112 and may be provided on the second pixel 112. That is, referring to FIG. 2, the pixel corresponding regions 131, 132, 133, and 134 of the CSLA 130 may be provided to respectively face the pixels 111, 112, 113, and 114 corresponding thereto. The first pixel corresponding region 131, the second pixel corresponding region 132, the third pixel corresponding region 133, and the fourth pixel corresponding region 134 may be provided diagonally in a 2×2 arrangement in the first direction (X direction) and the second direction (Y direction). The CSLA 130 may include a plurality of nanoposts NP in each of the pixel corresponding regions 131, 132, 133, and 134. The nanoposts NP of the CSLA 130 may be configured such that color separation of separating incident light according to a wavelength occurs only between adjacent pixels. The nanoposts NP of the CSLA 130 may be configured such that color separation occurs only within a unit pixel arrangement (a 2×2 arrangement). For example, the CSLA 130 may be configured such that the light of the first wavelength included in incident light Li incident on the pixel corresponding regions 131, 132, 133, and 134 is condensed on at least one of the first pixel 111 or the second pixel 112, and such that the light of the second wavelength included in the incident light Li incident on the pixel corresponding regions 131, 132, 133, and 134 is condensed on at least one of the third pixel 113 or the fourth pixel 114. For example, as shown in FIG. 2, when the four pixel corresponding regions 131, 132, 133, and 134 are diagonally arranged in a 2×2 arrangement in correspondence to the four pixels 111, 112, 113, and 114, the CSLA 130 may be configured such that the light of the second wavelength included in the incident light Li incident on the first pixel corresponding region 131 is condensed on at least one of the third pixel 113 or the fourth pixel 114 adjacent to the first pixel 111. In addition, for example, the CSLA 130 may be configured such that the light of the first wavelength included in the incident light Li incident on the third pixel corresponding region 133 is condensed on at least one of the first pixel 111 or the second pixel 112 adjacent to the third pixel 113.

The nanoposts NP of the CSLA 130 may be configured to form different phase profiles in the light of the first wavelength and the light of the second wavelength included in the incident light Li so that color separation occurs only within the unit pixel arrangement. Because the refractive index of a material differs depending on the wavelength of reacting light, the CSLA 130 may provide different phase profiles with respect to the light of the first wavelength and the light of the second wavelength. In other words, because the same material has a different refractive index according to the wavelength of light reacting to the material and a phase delay experienced by light when passing through the material is also different for each wavelength, a different phase profile may be formed for each wavelength. For example, a refractive index of the first pixel corresponding region 131 with respect to the light of the first wavelength may be different from a refractive index of the first pixel corresponding region 131 with respect to the light of the second wavelength, and a phase delay experienced by the light of the first wavelength passing through the first pixel corresponding region 131 and a phase delay experienced by the light of the second wavelength passing through the first pixel corresponding region 131 may be different from each other, and thus, when the CSLA 130 is designed considering the characteristics of light, different phase profiles may be provided with respect to the light of the first wavelength and the light of the second wavelength. To this end, each of the pixel corresponding regions 131, 132, 133, and 134 of the CSLA 130 may include the plurality of nanoposts NP each having a cylindrical shape.

One or more nanoposts NP may be disposed in each of the pixel corresponding regions 131, 132, 133, and 134 of the CSLA 130, and the shape, size, space, and/or arrangement of the nanoposts NP may vary depending on the region. For example, each of the pixel corresponding regions 131, 132, 133, and 134 may include one or more nanoposts NP. The size, shape, space, and/or arrangement of the nanoposts NP are configured such that the light of the first wavelength is condensed on the first pixel 111 and the second pixel 112 and the light of the second wavelength is condensed on the third pixel 113 and the fourth pixel 114, through the CSLA 130.

The CSLA 130 may include the nanoposts NP arranged in a specific rule so that the light of the first wavelength and the light of the second wavelength have the first and second phase profiles, respectively. The rule may be applied to parameters, such as the shape of the nanoposts NP, sizes (width and height), a distance between the nanoposts NP, and the arrangement form thereof, and these parameters may be determined according to a phase profile to be implemented through the CSLA 130. A flat lens may be further provided on the CSLA 130.

The cross-sectional diameters of the nanoposts NP may have sub-wavelength dimensions. The sub-wavelength refers to a wavelength less than a wavelength band of light to be branched. The nanoposts NP may have dimensions less than those of the first and second wavelengths for each pixel corresponding region. When the incident light Li is a visible ray, the cross-sectional diameters of the nanoposts NP may have dimensions less than 400 nm, 300 nm, or 200 nm. Although not shown, the nanoposts NP may be a combination of two or more posts stacked in a height direction (Z direction). In addition, although it is described that the CSLA 130 includes one layer, the CSLA 130 may have a structure in which a plurality of layers are stacked. The nanoposts NP may be configured such that color separation occurs only between adjacent pixels, and the nanoposts NP may be configured such that color separation occurs only within the unit pixel arrangement, thereby reducing crosstalk with other neighboring unit pixel units.

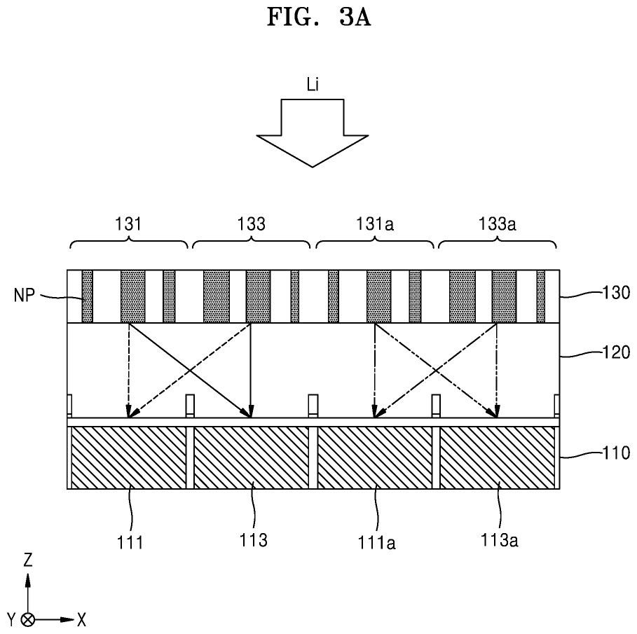

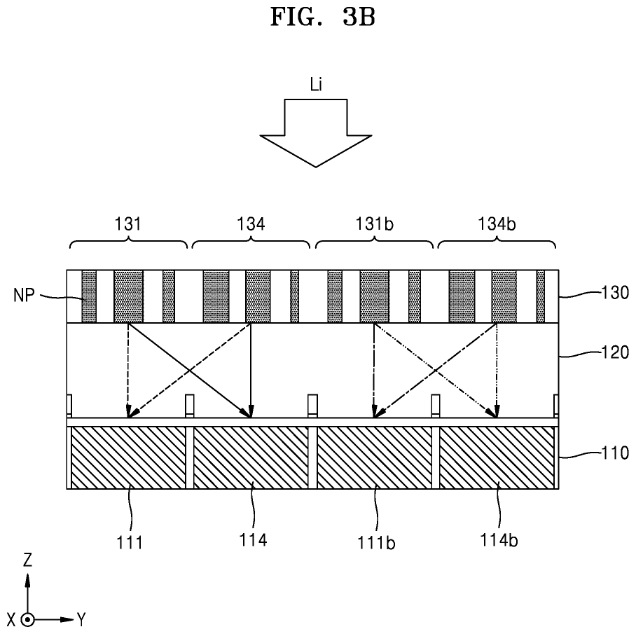

FIG. 3A is a diagram schematically illustrating a cross section of an image sensor of FIG. 2 in a first direction, and FIG. 3B is a diagram schematically illustrating a cross section of the image sensor of FIG. 2 in a second direction.

Referring to FIG. 3A, the CSLA 130 may be configured such that light (solid line) of a second wavelength included in the incident light Li incident on the first pixel corresponding region 131 is color separated and is condensed on the third pixel 113 adjacent to the first pixel 111, and may be configured such that light (dotted line) of a first wavelength included in the incident light Li incident on the first pixel corresponding region 131 is condensed on the first pixel 111. The CSLA 130 may be configured such that the light (dotted line) of the first wavelength included in the incident light Li incident on the third pixel corresponding region 133 is color separated and is condensed on the first pixel 111 adjacent to the third pixel 113, and may be configured such that the light (solid line) of the second wavelength included in the incident light Li incident on the third pixel corresponding region 133 is condensed on the third pixel 113. The CSLA 130 may be configured such that color separation occurs only between the adjacent pixels (e.g., 111 and 113) in the first direction (X direction) within a unit pixel arrangement, and color separation does not occur between the pixel (e.g., 113) within the unit pixel arrangement and a pixel (e.g., 111a) within another unit pixel arrangement adjacent thereto in the first direction (X direction).

Also, referring to FIG. 3B, the CSLA 130 may be configured such that the light (solid line) of the second wavelength included in the incident light Li incident on the first pixel corresponding region 131 is condensed on the fourth pixel 114 adjacent to the first pixel 111, and may be configured such that the light (dotted line) of the first wavelength included in the incident light Li incident on the first pixel corresponding region 131 is condensed on the first pixel 111. The CSLA 130 may be configured such that the light (dotted line) of the first wavelength included in the incident light Li incident on the fourth pixel corresponding region 134 is condensed on the first pixel 111 adjacent to the fourth pixel 114, and may be configured such that the light (solid line) of the second wavelength included in the incident light Li incident on the fourth pixel corresponding region 134 is condensed on fourth pixel 114. The CSLA 130 may be configured such that color separation occurs only between the adjacent pixels (e.g., 111 and 114) in the second direction (Y direction) within the unit pixel arrangement, and color separation does not occur between the pixel (e.g., 114) within the unit pixel arrangement and a pixel (e.g., 111b) within another unit pixel arrangement adjacent thereto in the second direction (Y direction).

Referring to FIGS. 3A and 3B together, the light (dotted line) of the first wavelength condensed in the pixel corresponding regions (the first pixel corresponding region 131, the third pixel corresponding region 133, and the fourth pixel corresponding region 134) having an area larger than an area of the first pixel 111 may be condensed on the first pixel 111. As in the case of the first pixel 111 described above, light of each wavelength condensed in corresponding regions having an area larger than an area of each pixel may be condensed on each of the second pixel 112, the third pixel 113, and the fourth pixel 114. Accordingly, an amount of light condensed on each pixel may be increased compared to an image sensor having a pixel corresponding region of a similar area to an area of a pixel.

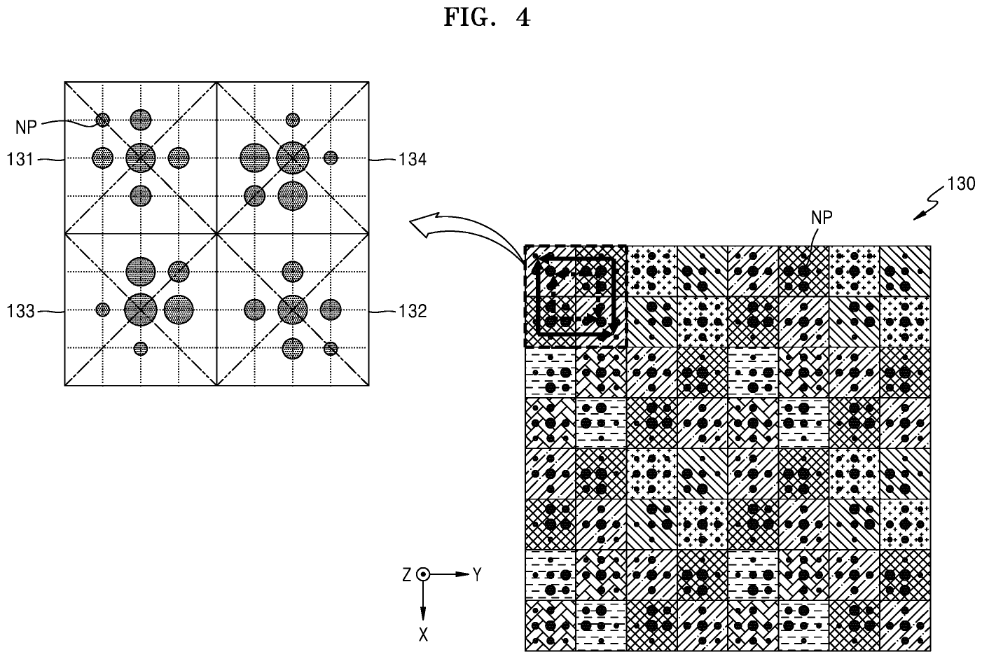

FIG. 4 is a diagram schematically illustrating a cross section of the CSLA 130 of FIG. 2.

Referring to FIG. 4, the CSLA 130 may include pixel corresponding regions 131, 132, 133, and 134 in a 2×2 arrangement, and the pixel corresponding regions 131, 132, 133, and 134 may include, for example, the nanoposts NP in a cylindrical shape having a circular cross section. Each of the pixel corresponding regions 131, 132, 133, and 134 may include the nanoposts NP symmetrically with respect to a diagonal line (one-dot dashed line) of a 2×2 arrangement, and may include the nanoposts NP asymmetrically with respect to a line (two-dot dashed line) connecting centers of two adjacent outer lines of the 2×2 arrangement. Each of the pixel corresponding regions 131, 132, 133, and 134 may include the nanoposts NP asymmetrically with respect to a line extending in the first direction (X direction) from the center of each of the pixel corresponding regions 131, 132, 133, and 134, and may include the nanoposts NP asymmetrically with respect to a line extending from the center of each of the pixel corresponding regions 131, 132, 133, and 134 in the second direction (Y direction). According to such an arrangement structure, color separation may occur only between adjacent pixels included in the 2×2 arrangement in the first direction (X direction) and the second direction (Y direction), and color separation may occur only between first to fourth pixels included in the 2×2 arrangement. For example, among lights incident on the first pixel corresponding region 131, light of a first wavelength (e.g., green light) may be condensed on the first pixel 111, and light of a second wavelength (e.g., magenta light) may be color separated into the third pixel 113 and the fourth pixel 114. Among lights incident on the third pixel corresponding region 133, the light of the second wavelength (e.g., magenta light) may be condensed on the third pixel 113, and the light of the first wavelength (e.g., green light) may be color separated into the first pixel 111 and the second pixel 112.

The plurality of nanoposts NP may be provided asymmetrically with respect to at least one of a line extending in the first direction (X direction) from the center of each of the pixel corresponding regions 131, 132, 133, and 134 or a line extending in the second direction (Y direction) from the center of each of the pixel corresponding regions 131, 132, 133, and 134 within each of the pixel corresponding regions 131, 132, 133, and 134.

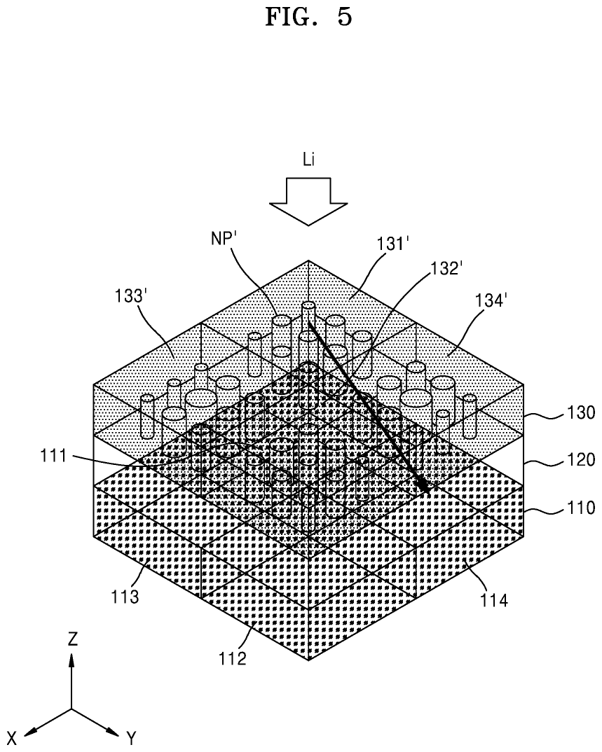

FIG. 5 is a diagram illustrating a pixel array of an image sensor including a CSLA 130′ according to an embodiment.

Referring to FIG. 5, the CSLA 130′ maybe configured such that color separation occurs only between adjacent pixels in the second direction (Y direction) within a unit pixel arrangement, and color separation may not occur in the first direction (X direction). For example, as shown in FIG. 5, when four pixel corresponding regions 131′, 132′, 133′, and 134′ respectively correspond to the four pixels 111, 112, 113, and 114 and are diagonally arranged in a 2×2 arrangement, the CSLA 130′ maybe configured such that light of a second wavelength included in the incident light Li incident on the first pixel corresponding region 131′ is condensed on the fourth pixel 114 adjacent to the first direction (X direction) of the first pixel 111. Also, for example, the CSLA 130′ maybe configured such that light of a first wavelength included in incident light Li incident on the fourth pixel corresponding region 134 is condensed on the first pixel 111 in a direction opposite to the second direction (Y direction) of the fourth pixel 114.

To this end, each of the first to fourth pixel corresponding regions 131′, 132′, 133′, and 134′ of the CSLA 130′ may include, for example, a plurality of nanoposts NP′ in a cylindrical shape, the nanoposts NP′ maybe provided symmetrically with respect to a line extending in the second direction (Y direction) from the center of each of the first to fourth pixel corresponding regions 131′, 132′, 133′, and 134′, and may be provided asymmetrically with respect to a line extending in the first direction (X direction) from the center of each of the first to fourth pixel corresponding regions 131′, 132′, 133′, and 134′.

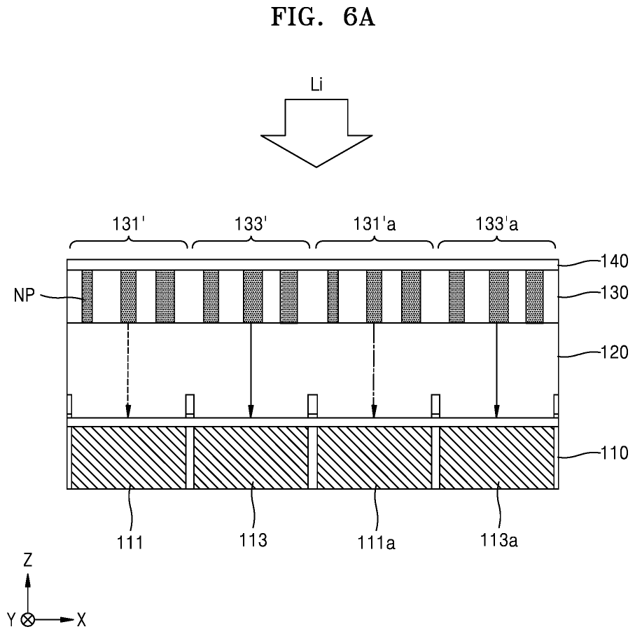

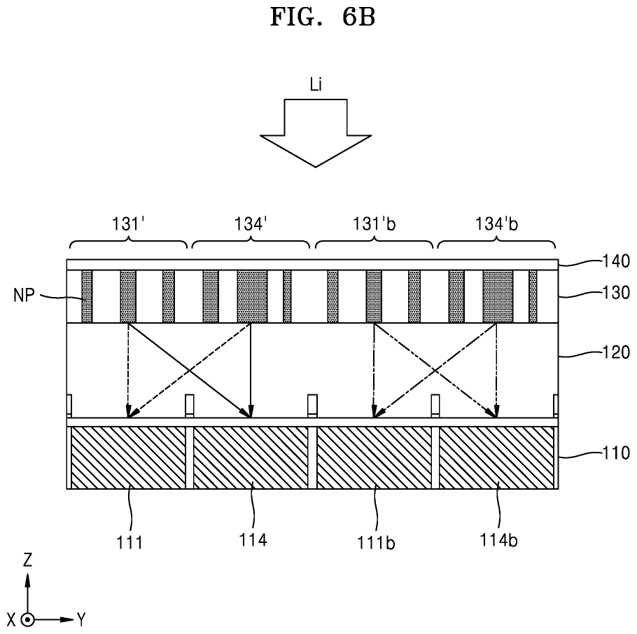

FIG. 6A is a diagram schematically illustrating a cross section of an image sensor of FIG. 5 in a first direction, and FIG. 6B is a diagram schematically illustrating a cross section of the image sensor of FIG. 5 in a second direction. Differences between FIGS. 6A and 6B and FIGS. 3A to 3B are mainly described.

Referring to FIGS. 6A and 6B, the CSLA 130 may be configured such that light (dotted line) of a first wavelength included in the incident light Li incident on the first pixel corresponding region 131 is condensed on the first pixel 111, and color separation may not occur in the first direction (X direction). In addition, the CSLA 130 may be configured such that the light (solid line) of the second wavelength included in the incident light Li incident on the third pixel corresponding region 133 is condensed on the third pixel 113, and similarly, color separation may not occur in the first direction (X direction). That is, unlike FIG. 3A in which color separation occurs in the first direction (X direction) and the second direction (Y direction), color separation occurs only in the second direction (Y direction), and color separation may not occur in the first direction (X direction).

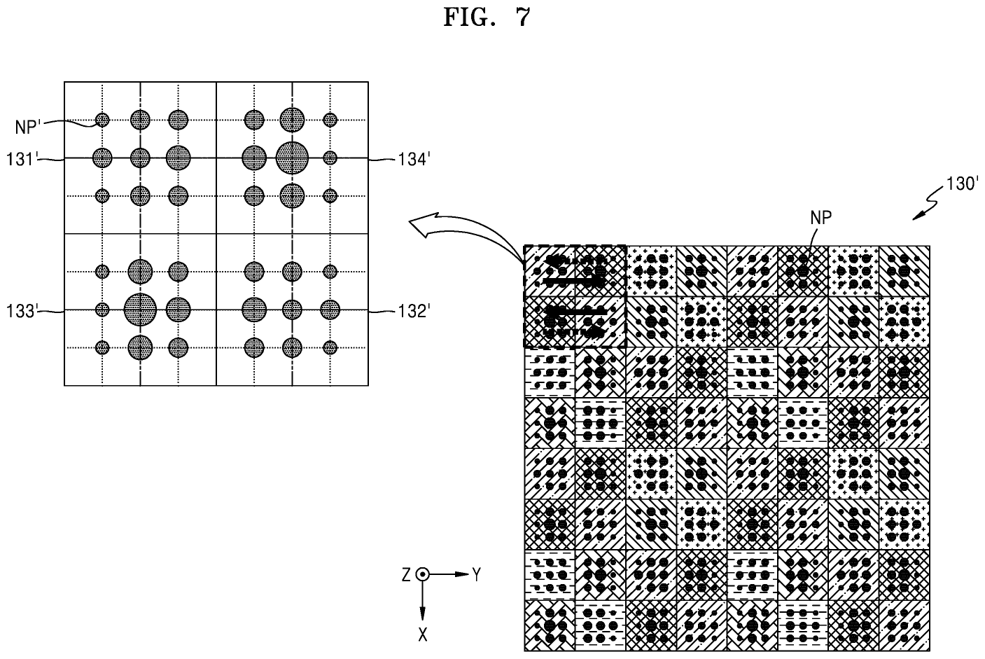

FIG. 7 is a diagram schematically illustrating a cross section of the CSLA 130′ of FIG. 5.

Referring to FIG. 7, the CSLA 130′ may include the pixel corresponding regions 131′, 132′, 133′, and 134′ in a 2×2 arrangement, and the pixel corresponding regions 131′, 132′, 133′, and 134′ may include, for example, nanoposts NP′ in a cylindrical shape having a circular cross section. Each of the first pixel corresponding region 131′, the second pixel corresponding region 132′, the third pixel corresponding region 133′, and the fourth pixel corresponding region 134′ may include the nanoposts NP′ symmetrically with respect to a line extending in the second direction (Y direction) from the center of each of the first pixel corresponding region 131′, the second pixel corresponding region 132′, the third pixel corresponding region 133′, and the fourth pixel corresponding region 134′ in the second direction (Y direction), and may include the nanoposts NP′ asymmetrically with respect to a line extending in the first direction (X direction) from the center of each of the first pixel corresponding region 131′, the second pixel corresponding region 132′, the third pixel corresponding region 133′, and the fourth pixel corresponding region 134′.

According to such an arrangement structure, color separation may occur only between adjacent pixels included in the 2×2 arrangement in the second direction (Y direction). For example, light of a second wavelength included in incident light incident on the first pixel corresponding region 131′ maybe condensed on the fourth pixel 114 adjacent to the second direction (Y direction) of the first pixel 111, and light of a first wavelength included in the incident light incident on the fourth pixel corresponding region 134′ maybe condensed on the first pixel 111 in a direction opposite to the second direction (Y direction) of the fourth pixel 114. That is, unlike the case of FIG. 4 in which color separation may occur in the first direction (X direction) and the second direction (Y direction), color separation may occur only in the second direction (Y direction).

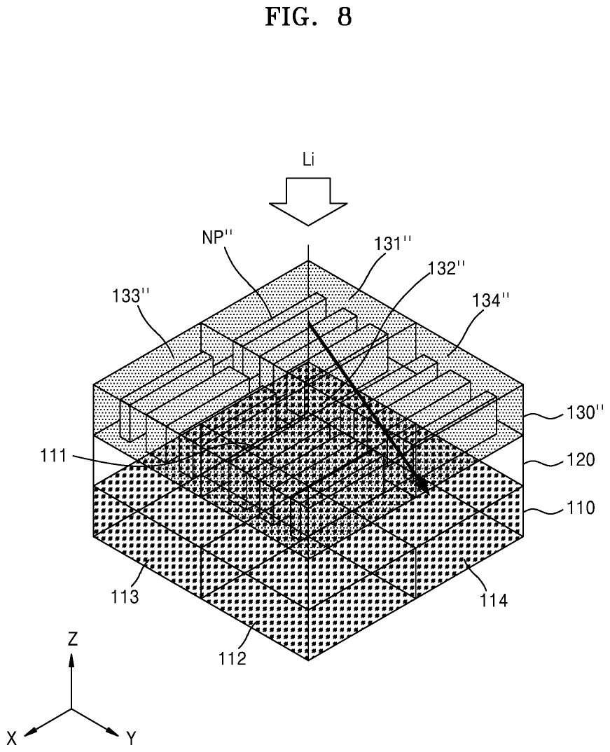

FIG. 8 is a diagram illustrating a pixel array of an image sensor including a CSLA 130″ according to an embodiment.

Referring to FIG. 8, the CSLA 130″ may include pixel corresponding regions 131″, 132″, 133″, and 134″ in a 2×2 arrangement, and the pixel corresponding regions 131″, 132″, 133″, and 134″ may include, for example, nanoposts NP″ in a hexahedral shape having a rectangular cross section. Each of the first pixel corresponding region 131″, the second pixel corresponding region 132″, the third pixel corresponding region 133″, and the fourth pixel corresponding region 134″ may include the nanoposts NP″ symmetrically with respect to a line extending in the second direction (Y direction) from the center of each of the first pixel corresponding region 131″, the second pixel corresponding region 132″, the third pixel corresponding region 133″, and the fourth pixel corresponding region 134″, and may include the nanoposts NP″ asymmetrically with respect to a line extending in the first direction (X direction) from the center of each of the first pixel corresponding region 131″, the second pixel corresponding region 132″, the third pixel corresponding region 133″, and the fourth pixel corresponding region 134″. According to such an arrangement structure, color separation may occur only between adjacent pixels included in the 2×2 arrangement in the second direction (Y direction). For example, light of a second wavelength included in incident light incident on the first pixel corresponding region 131″ maybe condensed on the third pixel 113 provided in the first direction (X direction) of the first pixel 111, and light of a first wavelength included in incident light incident on the third pixel corresponding region 133″ maybe condensed on the first pixel 111 provided in a direction opposite to the first direction (X direction) of the third pixel 113.

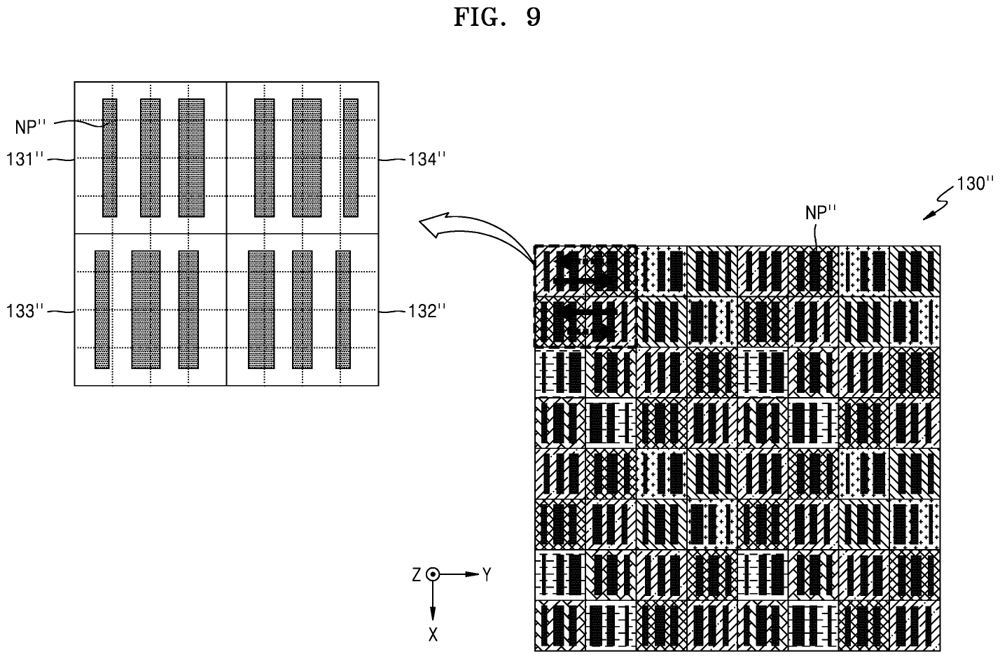

FIG. 9 is a diagram schematically illustrating a cross section of the CSLA 130″ of FIG. 8.

Referring to FIG. 9, the CSLA 130″ may include the pixel corresponding regions 131″, 132″, 133″, and 134″ in a 2×2 arrangement, and the pixel corresponding regions 131″, 132″, 133″, and 134″ may include the nanoposts NP″ in a hexahedral shape having a rectangular cross section.

The cross-sectional shapes of the nanoposts NP″ are illustrated as an example, but are not limited thereto, and some nanoposts having various cross-sectional shapes may be included. For example, nanoposts having an asymmetrical cross-sectional shape having different widths in the first direction (X direction) and in the second direction (Y direction) may be employed in nanoposts included in a pixel corresponding region.

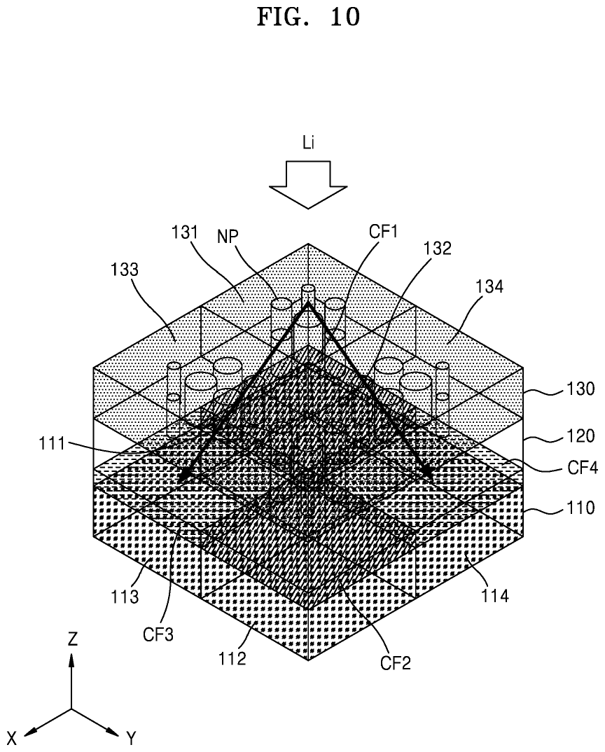

FIG. 10 is a diagram illustrating a pixel array of an image sensor including a CSLA according to an embodiment.

Referring to FIG. 10, the pixel array of the image sensor may include a plurality of color filters CF1, CF2, CF3, and CF4 respectively corresponding to arrangements of the plurality of pixels 111, 112, 113, and 114 of the sensor substrate 110 between the sensor substrate 110 and the spacer layer 120. The color filters CF1, CF2, CF3, and CF4 may be designed to transmit only light of a specific wavelength band. For example, the first color filter CF1 and the second color filter CF2 may cause only light of a first wavelength (e.g., green light) to transmit therethrough and proceed to the first pixel 111 and the second pixel 112 provided thereunder, respectively. In addition, the third color filter CF3 and the fourth color filter CF4 may cause only light of a second wavelength (e.g., magenta light) to transmit therethrough and proceed to the third pixel 113 and the fourth pixel 114 provided thereunder, respectively.

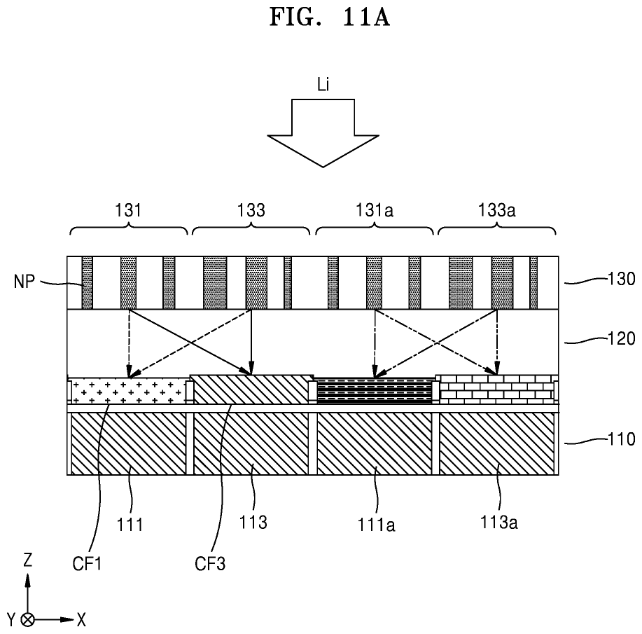

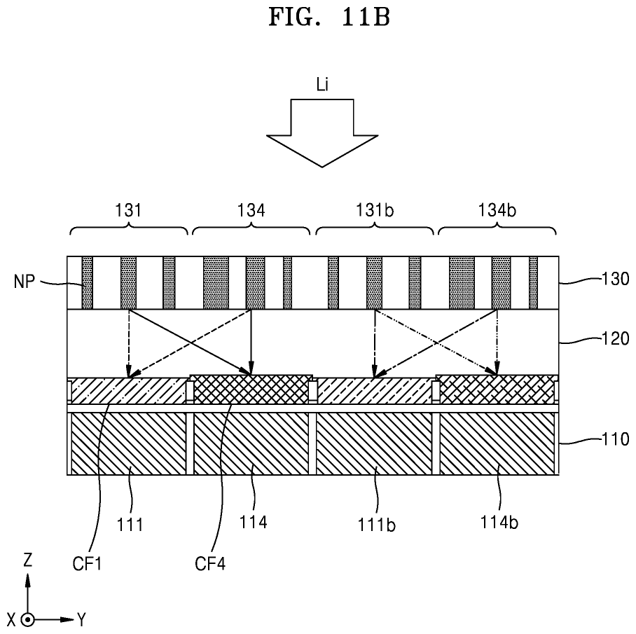

FIG. 11A is a diagram schematically illustrating a cross section of an image sensor of FIG. 10 in the first direction (X direction), and FIG. 11B is a diagram schematically illustrating a cross section of the image sensor of FIG. 10 in the second direction (Y direction).

Referring to FIG. 11A, light (dotted line) of a first wavelength included in the incident light Li incident on the first pixel corresponding region 131 may transmit through the first color filter CF1 and be condensed on the first pixel 111, and light (solid line) of a second wavelength may be color separated to transmit through the third color filter CF3 and be condensed on the third pixel 113 adjacent to the first pixel 111. The CSLA 130 may be configured such that the light (solid line) of the second wavelength included in the incident light Li incident on the third pixel corresponding region 133 transmits through the third color filter CF3 and is condensed on the third pixel 113, and the light (dotted line) of the first wavelength is color separated to transmit through the first color filter CF1 and is condensed on the first pixel 111 adjacent to the third pixel 113.

In addition, referring to FIG. 11B, the CSLA 130 may be configured such that the light (dotted line) of the first wavelength included in the incident light Li incident on the first pixel corresponding region 131 transmits through the first color filter CF1 and is condensed on the first pixel 111, and the light (solid line) of the second wavelength is color separated to transmit through the fourth color filter CF4 and is condensed on the fourth pixel 114 adjacent to the first pixel 111. The CSLA 130 may be configured such that the light (solid line) of the second wavelength included in the incident light Li incident on the fourth pixel corresponding region 134 transmits through the fourth color filter CF4 and is condensed on the fourth pixel 114, and the light (dotted line) of the first wavelength transmits through the first color filter CF1 and is condensed on the first pixel 111 adjacent to the fourth pixel 114.

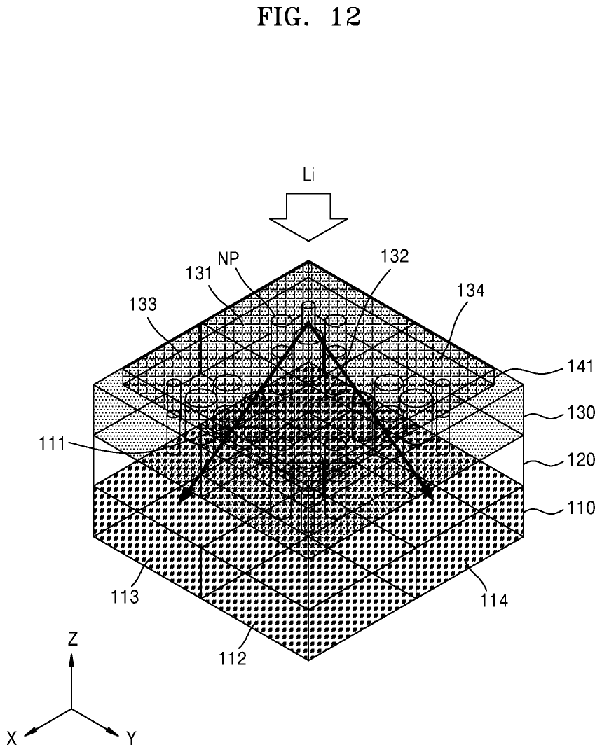

FIG. 12 is a diagram illustrating a pixel array of an image sensor including the CLSA 130 according to an embodiment.

Referring to FIG. 12, the pixel array of the image sensor may include a flat lens 141 on the CSLA 130. The flat lens 141 may be etched at regular intervals according to a pixel arrangement of the sensor substrate 110 and may have an area smaller than the area occupied by pixels of a unit pixel arrangement on the sensor substrate 110. For example, as shown in FIG. 12 of the sensor substrate 110, when the first pixel 111, the second pixel 112, the third pixel 113, and the fourth pixel 114 are provided in a 2×2 unit pixel arrangement, the flat lens 141 surrounding the 2×2 unit pixel arrangement may be provided on the CSLA 130. That is, the flat lens 141 facing the unit pixel arrangement in a vertical direction of the unit pixel arrangement and having four etched circumferences may be provided on the CSLA 130. As another embodiment, the flat lens 141 having a pattern (e.g., a pattern in a hole shape) may be provided on the CSLA 130. The flat lens 141 having the pattern may reduce a reflectivity of incident light.

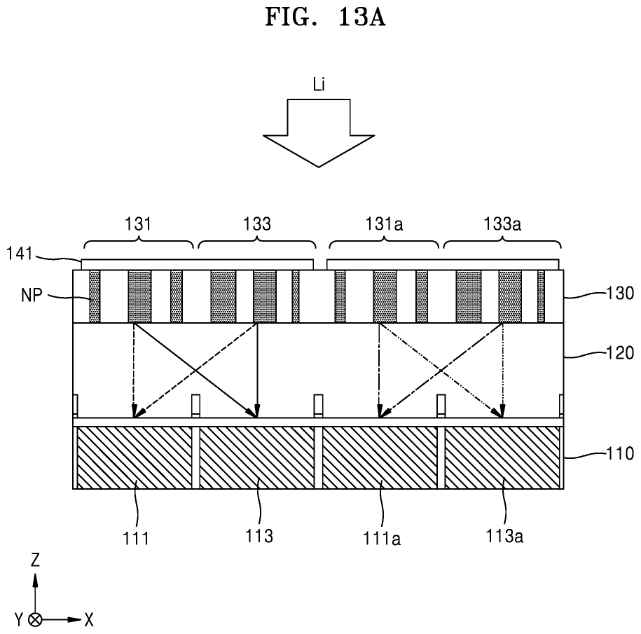

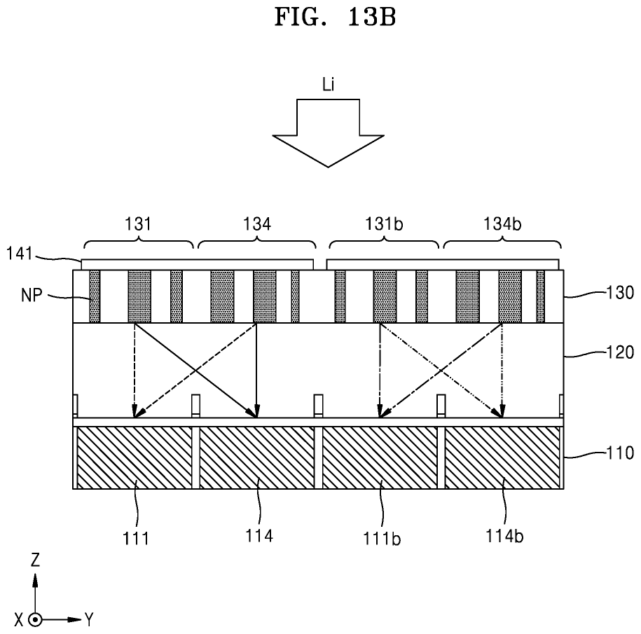

FIG. 13A is a diagram schematically illustrating a cross section of an image sensor of FIG. 12 in the first direction (X direction), and FIG. 13B is a diagram schematically illustrating a cross section of the image sensor of FIG. 12 in the second direction (Y direction).

Referring to FIGS. 13A and 13B, the pixel array of the image sensor may include the flat lens 141 on the CSLA 130. Referring to FIG. 13A, the flat lens 141 may be etched at two pixel intervals in the first direction (X direction). Referring to FIG. 13B, the flat lens 141 may be etched at two pixel intervals in the second direction (Y direction).

The image sensor and the electronic device including the CSLA may improve a light utilization efficiency. In addition, the image sensor including the CSLA may reduce crosstalk between adjacent pixels.

The pixel arrays of the image sensors including the CSLAs 130, 130′, and 130″ shown in FIGS. 2 to 13B are examples. In addition, CSLA of various types may be obtained through the above optimization design, according to, for example, the sizes and thicknesses of the CSLAs 130, 130′, and 130″, color characteristics and pitches between pixels in the image sensor, to which the CSLAs 130, 130′, and 130″ are to be applied, distances between the CSLAs 130, 130′, and 130″ and the image sensor, an incidence angle of the incident light.

FIG. 14 is a diagram conceptually illustrating a pixel arrangement of the sensor substrate 110 according to an embodiment.

Referring to FIG. 14, for example, the first pixel 111 and the second pixel 112 each sensing light of a first wavelength, the third pixel 113 and the fourth pixel 114 each sensing light of a second wavelength, a fifth pixel 111a and a sixth pixel 112a each sensing light of a third wavelength, a seventh pixel 113a and an eighth pixel 114a each sensing light of a fourth wavelength, a ninth pixel 111b and a tenth pixel 112b each sensing light of a fifth wavelength, an eleventh pixel 113b and a twelfth pixel 114b each sensing light of a sixth wavelength, a thirteenth pixel 111c and a fourteenth pixel 112c sensing the light of the first wavelength, and a fifteenth pixel 113c and a sixteenth pixel 114c sensing the light of the second wavelength may be provided on the sensor substrate 110 of FIG. 2.

The lights of the first to sixth wavelengths described above may have different wavelengths. For example, the light of the first wavelength may be green (G) light, the light of the second wavelength may be magenta (M) light, the light of the third wavelength may be red (R) light, the light of the fourth wavelength may be cyan (C) light, the light of the fifth wavelength may be blue (B) light, and the light of the sixth wavelength may be yellow (Y) light. The light of the first wavelength may have a complementary color relationship with the light of the second wavelength, the light of the third wavelength may have a complementary color relationship with the light of the fourth wavelength, and the light of the fifth wavelength may have a complementary color relationship with the light of the sixth wavelength. In addition, the plurality of pixels may be diagonally arranged in a 2×2 arrangement in the first direction (X direction) and the second direction (Y direction) on the sensor substrate 110 between pixels sensing light having a complementary color relationship.

For example, the first pixel 111 and the second pixel 112 sensing the green light and the third pixel 113 and fourth pixel 114 sensing the magenta light may be diagonally arranged in the 2×2 arrangement. In addition, the fifth pixel 111a and the sixth pixel 112a 114 sensing the red light and the seventh pixel 113a and the eighth pixel 114a 114 sensing the cyan light may be diagonally arranged in the 2×2 arrangement. In addition, the ninth pixel 111b and the tenth pixel 112b 114 sensing the blue light and the eleventh pixel 113b and the twelfth pixel 114b 114 sensing the yellow light may be diagonally arranged in the 2×2 arrangement. In addition, the thirteenth pixel 111c and the fourteenth pixel 112c sensing the green light and the fifteenth pixel 113c and the sixteenth pixel 114c sensing the magenta light may be diagonally arranged in the 2×2 arrangement in a diagonal direction of the 2×2 arrangement in which the first to fourth pixels 111, 112, 113, and 114 are arranged.

That is, the fifth pixel 111a, the sixth pixel 112a, the seventh pixel 113a, and the eighth pixel 114a may be provided in the 2×2 arrangement, the fifth pixel 111a and the sixth pixel 112a may be provided in the diagonal direction, the seventh pixel 113a and the eighth pixel 114a may be provided in the diagonal direction, and the fifth pixel 111a and the eighth pixel 114a may be provided in the second direction (Y direction), and the fifth pixel 111a and the seventh pixel 113a may be provided in the first direction (X direction) on the sensor substrate 110. The ninth pixel 111b, the tenth pixel 112b, the eleventh pixel 113b, and the twelfth pixel 114b may be provided in the 2×2 arrangement, the ninth pixel 111b and the tenth pixel 112b may be provided in the diagonal direction, the eleventh pixel 113b and the twelfth pixel 114b may be provided in the diagonal direction, the ninth pixel 111b and the twelfth pixel 114b may be provided in the second direction (Y direction), and the ninth pixel 111b and the eleventh pixel 113b may be provided in the first direction (X direction) on the sensor substrate 110. The thirteenth pixel 111c, the fourteenth pixel 112c, the fifteenth pixel 113c, and the sixteenth pixel 114c may be provided in the 2×2 arrangement, the thirteenth pixel 111c and the fourteenth pixel 112c may be provided in the diagonal direction, the fifteenth pixel 113c and the sixteenth pixel 114c may be provided in the diagonal direction, and the thirteenth pixel 111c and the sixteenth pixel 114c may be provided in the second direction (Y direction), and the thirteenth pixel 111c and the fifteenth pixel 113c may be provided in the first direction (X direction) on the sensor substrate 110.

The first to sixteenth pixels 111, 112, 113, 114, 111a, 112a, 113a, 114a, 111b, 112b, 113b, 114b, 111c, 112c, 113c, and 114c may be generally provided in a 4×4 arrangement. In addition, the 4×4 arrangement may be repeatedly provided on the sensor substrate 110. When a 2×2 arrangement pixel is referred to as a unit pixel arrangement 110A, a CSLA corresponding to the unit pixel arrangement 110A may be configured such that color separation occurs only within the unit pixel arrangement 110A, and crosstalk generated between neighboring unit pixel arrangements 110A may be reduced.

FIG. 14 is a diagram conceptually illustrating another embodiment of a pixel arrangement of a sensor substrate.

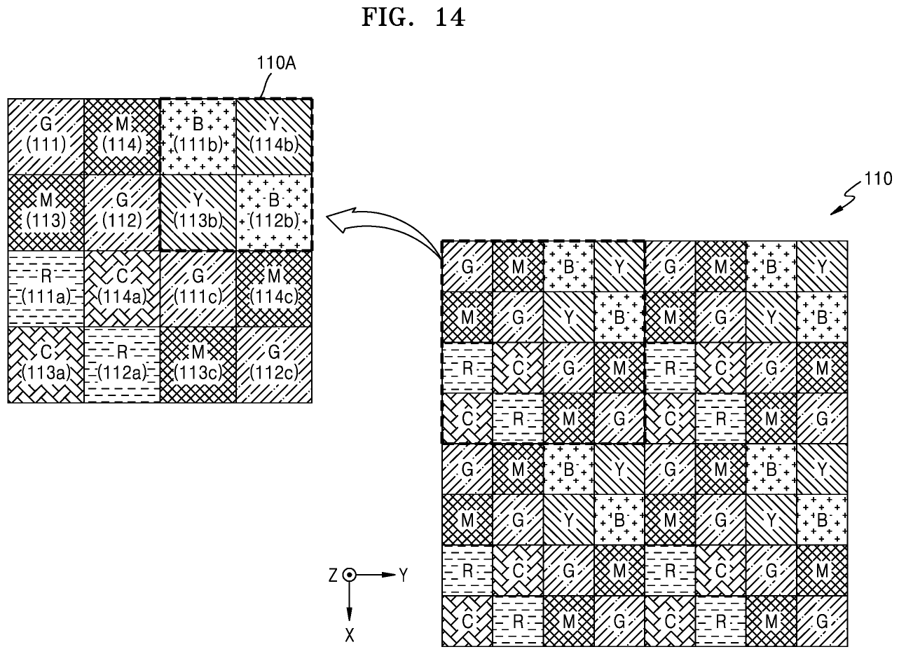

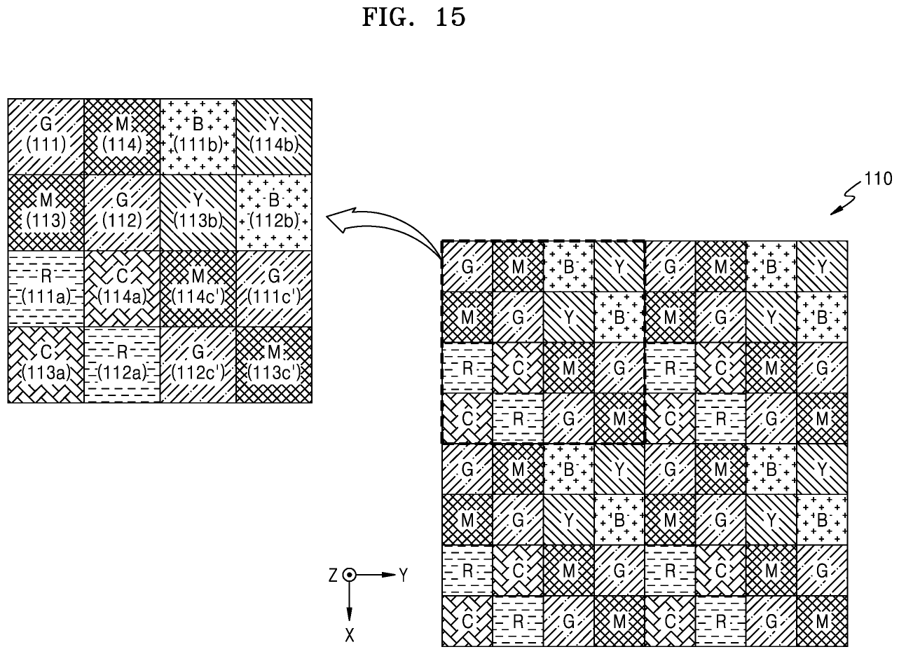

Differences between FIG. 14 and FIG. 14 are mainly described. Referring to FIG. 15, a 2×2 unit pixel arrangement in which thirteenth to sixteenth pixels 111c′, 112c′, 113c′, and 114c′ are arranged in an inverted diagonal may be provided in a diagonal direction of a 2×2 arrangement in which the first to fourth pixels 111, 112, 113, and 114 are arranged. For example, when the second pixel 112 sensing light of a first wavelength is provided between the first direction (X direction) and the second direction (Y direction) of the first pixel 111 sensing the light of the first wavelength in the 2×2 arrangement in which the first to fourth pixels 111, 112, 113, and 114 are arranged, the fourteenth pixel 112c′ sensing the light of the first wavelength may be provided between the first direction (X direction) and a direction opposite to the second direction (Y direction) of the thirteenth pixel 111c′ in a 2×2 arrangement in which the thirteenth to the sixteenth pixels 111c′, 112c′, 113c′, and 114c′ are arranged.

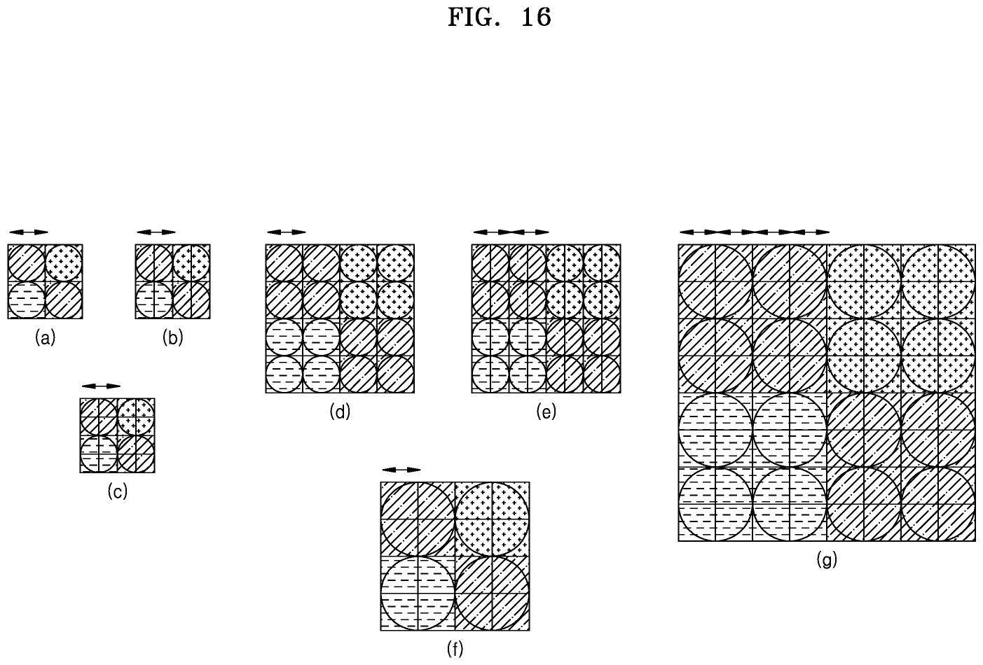

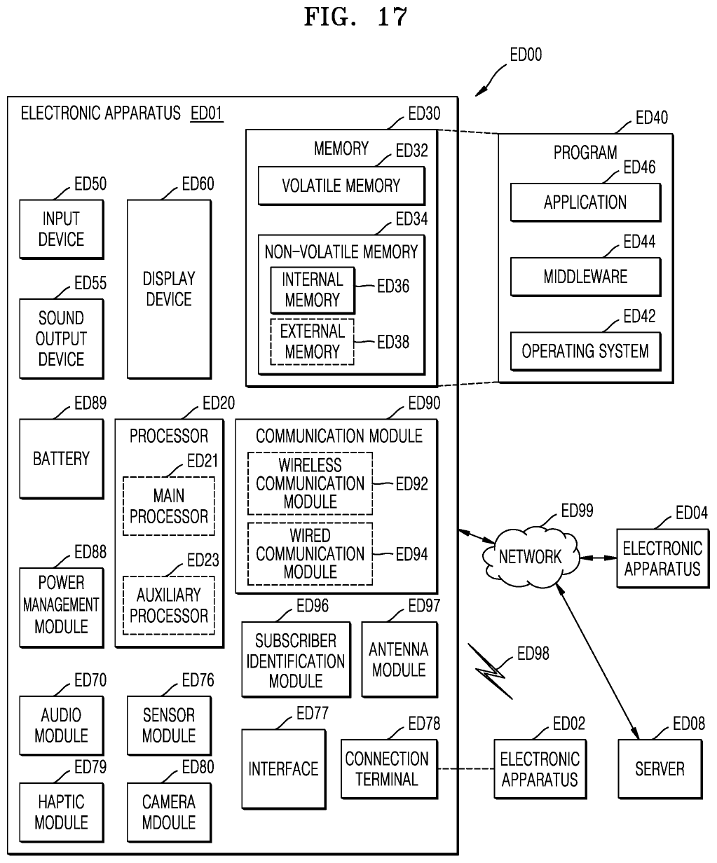

FIGS. 16A to 16G are diagrams conceptually illustrating a pixel array constituting a unit pixel arrangement.

Referring to FIG. 16A, each pixel may correspond to one photo diode. Referring to FIG. 16B, each pixel may correspond to two photodiodes. Referring to FIG. 16C, each pixel may correspond to four photodiodes. Referring to FIG. 16D, each pixel may include four sub-pixels, and each sub-pixel may correspond to one photodiode. Referring to FIG. 16E, each of pixels constituting a 2×2 unit pixel arrangement may include four sub-pixels, and each sub-pixel may correspond to two photodiodes. Referring to FIG. 16F, four pixels may correspond to one pixel unit. Referring to FIG. 16G, sixteen pixels may correspond to one pixel unit. The pixel array of FIGS. 16A to 16G may be used to perform an auto focusing (AF) function as well as imaging.

In the image sensor 1000 including the pixel array 1100 including the CSLA 130 described above, because light loss caused by a color filter, for example, an organic color filter rarely occurs, a sufficient light intensity may be provided to pixels even when sizes of the pixels are reduced. Therefore, an ultra-high resolution, ultra-small, and highly sensitive image sensor having hundreds of millions of pixels or more may be manufactured. Such an ultra-high resolution, ultra-small, and highly sensitive image sensor may be employed in various high-performance optical devices or high-performance electronic devices. For example, the electronic devices may include, for example, smart phones, personal digital assistants (PDAs), laptop computers, personal computers (PCs), a variety of portable devices, electronic devices, surveillance cameras, medical camera, automobiles, Internet of Things (IoT), augmented reality (AR) devices, virtual reality (VR) devices, various types of extended reality devices that expand experiences of users, other mobile or non-mobile computing devices and are not limited thereto.

In addition to the image sensor 1000, the electronic device may further include a processor controlling the image sensor, for example, an application processor (AP), to drive an operating system or an application program through the processor and control a plurality of hardware or software components, and perform various data processing and operations. The processor may further include a graphic processing unit (GPU) and/or an image signal processor. When the processor includes the image signal processor, an image (or video) obtained by the image sensor may be stored and/or output using the processor.

FIG. 17 is a block diagram schematically illustrating an electronic device including an image sensor according to some embodiments.

Referring to FIG. 17, in a network environment ED00, an electronic device ED01 may communicate with another electronic device ED02 through a first network ED98 (e.g., a short-range wireless communication network) or communicate with another electronic device ED04 and/or a server ED08 through a second network ED99 (e.g., a remote wireless communication network) The electronic device ED01 may communicate with the electronic device ED04 through the server ED08. The electronic device ED01 may include a processor ED20, a memory ED30, an input device ED50, a sound output device ED55, a display apparatus ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. The electronic device ED01 may omit some (e.g., the display apparatus ED60) of the components or may further include other components. One or more of the components may be implemented as an integrated circuit. For example, the sensor module ED76 (e.g., a fingerprint sensor, an iris sensor, and/or an illumination sensor) may be embedded in the display apparatus ED60 (e.g., a display)

The processor ED20 may be configured to execute software (e.g., a program ED40) to control one or a plurality of components (hardware or software components) of the electronic device ED01, the components being connected to the processor ED20, and to perform various data processing or calculations. As part of the data processing or calculations, the processor ED20 may be configured to load a command and/or data received from other components (e.g., the sensor module ED76 and/or the communication module ED90) into the volatile memory ED32, process the command and/or the data stored in a volatile memory ED32, and store resultant data in a nonvolatile memory ED34. The processor ED20 may include a main processor ED21 (e.g., a central processing unit (CPU) and/or an application processor (AP)) and an auxiliary processor ED23 (e.g., a graphics processing unit (GPU), an image signal processor, a sensor hub processor, and/or a communication processor) which may independently operate or operate with the main processor ED21. The auxiliary processor ED23 may use less power than the main processor ED21 and may perform specialized functions.

When the main processor ED21 is in an inactive state (a sleep state), the auxiliary processor ED23 may take charge of an operation of controlling functions and/or states related to one or more components (e.g., the display apparatus ED60, the sensor module ED76, the communication module ED90) from among the components of the electronic device ED01, or when the main processor ED21 is in an active state (an application execution state), the auxiliary processor ED23 may perform the same operation along with the main processor ED21. The auxiliary processor ED23 (e.g., the image signal processor and/or the communication processor) may be realized as part of other functionally-related components (e.g., the camera module ED80 and/or the communication module ED90)

The memory ED30 may store various data required by the components (e.g., the processor ED20 and/or the sensor module ED76) of the electronic device ED01. The data may include, for example, software (e.g., the program ED40), input data and/or output data of a command related to the software. The memory ED30 may include the volatile memory ED32 and/or the nonvolatile memory ED34.

The program ED40 may be stored in the memory ED30 as software, and may include an operating system ED42, middleware ED44, and/or an application ED46.

The input device ED50 may receive a command and/or data to be used by the components (e.g., the processor ED20) of the electronic device ED01 from the outside of the electronic device ED01. The input device ED50 may include a microphone, a mouse, a keyboard, and/or a digital pen (e.g., a stylus pen)

The sound output device ED55 may output a sound signal to the outside of the electronic device ED01. The sound output device ED55 may include a speaker and/or a receiver. The speaker may be used for a general purpose, such as multimedia playing or recording playing, and the receiver may be used to receive an incoming call. The receiver may be coupled to the speaker as part of the speaker or may be realized as a separate device.

The display apparatus ED60 may visually provide information to the outside of the electronic device ED01. The display apparatus ED60 may include a display, a hologram device, or a controlling circuit for controlling a projector and a corresponding device. The display apparatus ED60 may include touch circuitry configured to sense a touch operation and/or sensor circuitry (e.g., a pressure sensor) configured to measure an intensity of a force generated by the touch operation.

The audio module ED70 may convert sound into an electrical signal or an electrical signal into sound. The audio module ED70 may obtain sound via the input device ED50 or may output sound via the sound output device ED55 and/or a speaker and/or a headphone of an electronic device (e.g., the electronic device ED02) directly or wirelessly connected to the electronic device ED01.

The sensor module ED76 may sense an operation state (e.g., power, temperature) of the electronic device ED01 or an external environmental state (e.g., a user state) and generate electrical signals and/or data values corresponding to the sensed state. The sensor module ED76 may include a gesture sensor, a gyro-sensor, an atmospheric sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface ED77 may support one or a plurality of designated protocols to be used for the electronic device ED01 to be directly or wirelessly connected to another electronic device (e.g., the electronic device ED02) The interface ED77 may include a high-definition multimedia interface (HDMI) interface, a universal serial bus (USB) interface, an SD card interface, and/or an audio interface.

A connection terminal ED78 may include a connector, through which the electronic device ED01 may be physically connected to another electronic device (e.g., the electronic device ED02) The connection terminal ED78 may include an HDMI connector, a USB connector, an SD card connector, and/or an audio connector (e.g., a headphone connector)

A haptic module ED79 may convert an electrical signal into a mechanical stimulus (e.g., vibration and/or motion) or an electrical stimulus which is recognizable to a user via haptic or motion sensation. The haptic module ED79 may include a motor, a piezoelectric device, and/or an electrical stimulus device.

The camera module ED80 may capture a still image and a video. The camera module ED80 may include a lens assembly including one or a plurality of lenses, the image sensor 1000 described above, image signal processors, and/or flashes. The lens assemblies included in the camera module ED80 may collect light emitted from an object, an image of which is to be captured.

The power management module ED88 may manage power supplied to the electronic device ED01. The power management module 8388 maybe realized as part of a power management integrated circuit (PMIC).

The battery ED89 may supply power to the components of the electronic device ED01. The battery ED89 may include a non-rechargeable primary battery, rechargeable secondary battery, and/or a fuel battery.

The communication module ED90 may support establishment of direct (wired) communication channels and/or wireless communication channels between the electronic device ED01 and other electronic devices (e.g., the electronic device ED02, the electronic device ED04, and/or the server ED08) and communication performance through the established communication channels. The communication module ED90 may include one or a plurality of communication processors separately operating from the processor ED20 (e.g., an application processor) and supporting direct communication and/or wireless communication. The communication module ED90 may include a wireless communication module ED92 (a cellular communication module, a short-range wireless communication module, a global navigation satellite system (GNSS) communication module, and/or a wired communication module ED94 (e.g., a local area network (LAN) communication module and/or a power line communication module) From these communication modules, a corresponding communication module may communicate with other electronic devices through a first network ED98 (a short-range wireless communication network, such as Bluetooth, Wifi direct, or infrared data association (IrDa)) or a second network ED99 (a remote communication network, such as a cellular network, the Internet, or a computer network (e.g., LAN and/or WAN)). Various types of communication modules described above may be integrated as a single component (e.g., a single chip) or realized as a plurality of components (a plurality of chips). The wireless communication module ED92 may identify and authenticate the electronic device ED01 within the first network ED98 and/or the second network ED99 by using subscriber information (e.g., international mobile subscriber identification (IMSI)) stored in the subscriber identification module ED96.

The antenna module ED97 may transmit a signal and/or power to the outside (e.g., other electronic devices) or receive the same from the outside. The antenna may include an emitter including a conductive pattern formed on a substrate (e.g., a printed circuit board (PCB)) The antenna module ED97 may include an antenna or a plurality of antennas. When the antenna module ED97 includes a plurality of antennas, an appropriate antenna which is suitable for a communication method used in the communication networks, such as the first network ED98 and/or the second network ED99, may be selected. Through the selected antenna, signals and/or power may be transmitted or received between the communication module ED90 and other electronic devices. In addition to the antenna, another component (e.g., a radio frequency integrated circuit (RFIC)) may be included in the antenna module ED97.

One or more of the components of the electronic device ED01 may be connected to one another and exchange signals (e.g., commands and/or data) with one another, through communication methods performed among peripheral devices (e.g., a bus, general purpose input and output (GPIO), a serial peripheral interface (SPI), and/or a mobile industry processor interface (MIPI))

The command or the data may be transmitted or received between the electronic device ED01 and another external electronic device ED04 through the server ED08 connected to the second network ED99. Other electronic devices ED02 and ED04 may be electronic devices that are homogeneous or heterogeneous types with respect to the electronic device ED01. All or part of operations performed in the electronic device ED01 may be performed by one or more other electronic devices ED02, ED04, and ED08. For example, when the electronic device ED01 has to perform a function or a service, instead of directly performing the function or the service, the one or more other electronic devices may be requested to perform part or all of the function or the service. The one or more other electronic devices receiving the request may perform an additional function or service related to the request and may transmit a result of the execution to the electronic device ED01. To this end, cloud computing, distribution computing, and/or client-server computing techniques may be used.

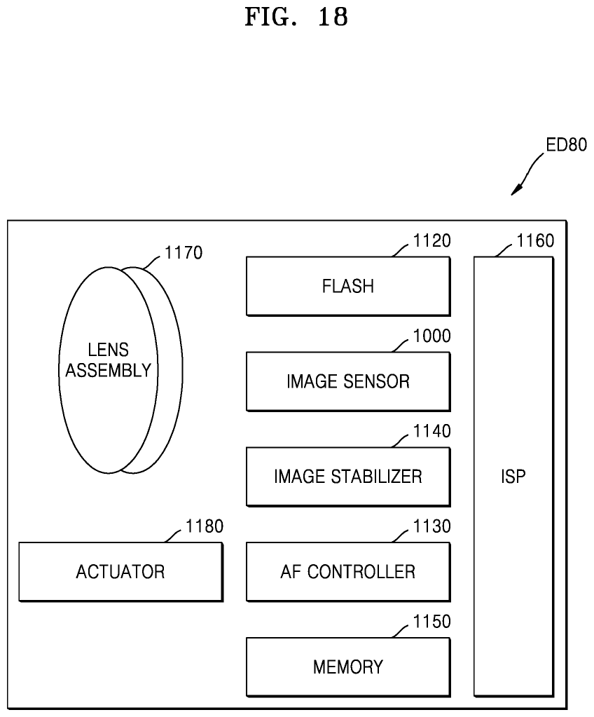

FIG. 18 is a block diagram illustrating the camera module ED80 included in the electronic device ED01 of FIG. 17.

Referring to FIG. 18, the camera module ED80 may include a lens assembly 1170, a flash 1120, an image sensor 1000, an image stabilizer 1140, an AF controller 1130, a memory 1150 (e.g., buffer memory), an actuator 1180, and/or an image signal processor (ISP) 1160.

The lens assembly 1170 may collect light emitted from an object that is to be captured. The lens assembly 1170 may include one or more optical lenses. The lens assembly 1170 may include a path switching member which switches the optical path toward the image sensor 1000. According to whether the path switching member is provided and the arrangement type with the optical lens, the camera module ED80 may have a vertical type or a folded type. The camera module ED80 may include a plurality of lens assemblies 1170, and in this case, the camera module ED80 may include a dual camera module, a 360-degree camera, or a spherical camera. Some of the plurality of lens assemblies 1170 may have the same lens properties (e.g., viewing angle, focal distance, auto-focus, F number, and/or optical zoom) or different lens properties. The lens assembly 1170 may include a wide-angle lens or a telephoto lens.

The actuator 1180 may drive the lens assembly 1170. At least some of the optical lens and the path switching member included in the lens assembly 1170 may be moved by the actuator 1180. The optical lens may be moved along the optical axis, and when the distance between adjacent lenses is adjusted by moving at least some of the optical lenses included in the lens assembly 1170, an optical zoom ratio may be adjusted.

The actuator 1180 may adjust the position of any one of the optical lenses in the lens assembly 1170 so that the image sensor 1000 maybe located at the focal length of the lens assembly 1170. The actuator 1180 may drive the lens assembly 1170 according to an AF driving signal transferred from the AF controller 1130.

The flash 1120 may emit light that is used to strengthen the light emitted or reflected from the object. The flash 1120 may emit visible light or infrared-ray light. The flash 1120 may include one or more light-emitting diodes (e.g., red-green-blue (RGB) LED, white LED, infrared LED, and/or ultraviolet LED), and/or a Xenon lamp. The image sensor 1000 maybe the image sensor 1000 described above with reference to FIG. 1, or may have a modified form. The image sensor 1000 may obtain an image corresponding to a subject by converting the light emitted or reflected from the subject and transferred through the lens assembly 1170 into an electrical signal.

The image sensor 1000 may include the CSLA 130 described above, and each pixel of the image sensor 1000 may include a plurality of photosensitive cells forming a plurality of channels, for example, the plurality of photosensitive cells arranged in a 2×2 array. All or some of the pixels may be used as AF pixels, and the image sensor 1000 may generate an AF driving signal from the signals from the plurality of channels in the AF pixels.

The image stabilizer 1140, in response to a motion of the camera module ED80 or the electronic apparatus ED01 including the camera module ED80, moves one or more lenses included in the lens assembly 1170 or the image sensor 1000 in a certain direction or controls the operating characteristics of the image sensor 1000 (e.g., adjusting of a read-out timing) in order to compensate for a negative influence of the motion. The image stabilizer 1140 may sense the movement of the camera module ED80 or the electronic apparatus ED01 by using a gyro sensor (not shown) or an acceleration sensor (not shown) arranged in or out of the camera module ED80. The image stabilizer 1140 maybe implemented as an optical type.

The AF controller 1130 may generate the AF driving signal from signal values sensed from the AF pixels in the image sensor 1000. The AF controller 1130 may control the actuator 1180 according to the AF driving signal.

The memory 1150 may store some or entire data of the image obtained through the image sensor 1000 for next image processing operation. For example, when a plurality of images are obtained at a high speed, obtained original data (e.g., Bayer-patterned data and/or high resolution data) is stored in the memory 1150, and a low resolution image is only displayed. Then, original data of a selected image (e.g., user selection) may be transferred to the image signal processor 1160. The memory 1150 maybe integrated with the memory ED30 of the electronic apparatus ED01, or may include an additional memory that is operated independently.

The ISP 1160 may perform image processing operations on the image obtained through the image sensor 1000 or the image data stored in the memory 1150. The image processing operations may include a depth map generation, a three-dimensional modeling, a panorama generation, extraction of features, an image combination, and/or an image compensation (e.g., noise reduction, resolution adjustment, brightness adjustment, blurring, sharpening, and/or softening) The image signal processor 1160 may perform controlling (e.g., exposure time control and/or read-out timing control) of the elements (e.g., image sensor 1000) included in the camera module ED80. The image processed by the image signal processor 1160 may be stored again in the memory 1150 for additional process, or may be provided to an external element of the camera module ED80 (e.g., the memory ED30, the display device ED60, the electronic apparatus ED02, the electronic apparatus ED04, and/or the server ED08) The image signal processor 1160 maybe integrated with the processor ED20, or may be configured as an additional processor that is independently operated from the processor ED20. When the image signal processor 1160 is configured as an additional processor separately from the processor ED20, the image processed by the image signal processor 1160 undergoes through an additional image treatment by the processor ED20 and then may be displayed on the display device ED60.

The AF controller 1130 maybe integrated with the image signal processor 1160. The image signal processor 1160 may generate the AF signal by processing signals from the AF pixels of the image sensor 1000, and the AF controller 1130 may convert the AF signal into a driving signal of the actuator 1180 and transfer the signal to the actuator 1180.

The image sensor 1000 according to some embodiments may be applied to various electronic apparatuses.

The image sensor 1000 according to some embodiments may be applied to a mobile phone or a smartphone, a tablet or a smart tablet, an AR device, a VR device, various types of extended reality devices that expand experiences of users, a digital camera or a camcorder, a laptop computer, or a television or a smart television. For example, the smartphone or the smart tablet, the AR device, the VR device, and various types of extended reality devices that expand experiences of users may include a plurality of high-resolution cameras each including a high-resolution image sensor. Depth information of objects in an image may be extracted, out focusing of the image may be adjusted, or objects in the image may be automatically identified by using the high-resolution cameras.

Also, the image sensor 1000 maybe applied to, for example, a smart refrigerator, a surveillance camera, a robot, a medical camera. For example, the smart refrigerator may automatically recognize food in the refrigerator by using the image sensor, and may notify the user of an existence of a certain kind of food, kinds of food put into or taken out through a smartphone. Also, the surveillance camera may provide an ultra-high-resolution image and may allow the user to recognize an object or a person in the image even in dark environment by using high sensitivity. The robot may be input to a disaster or industrial site that a person may not directly access, to provide the user with high-resolution images. The medical camera may provide high-resolution images for diagnosis or surgery, and may dynamically adjust a field of view.

Also, the image sensor 1000 maybe applied to a vehicle. The vehicle may include a plurality of vehicle cameras arranged on various locations. Each of the vehicle cameras may include the image sensor. The vehicle may provide a driver with various information about inside the vehicle or around the vehicle by using the plurality of vehicle cameras, and may automatically recognize an object or a person in the image to provide information required to the autonomous travel.

The image sensor and the electronic device including the CSLA may improve a light utilization efficiency. In addition, the image sensor including the CSLA may reduce crosstalk between adjacent pixels.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An image sensor comprising:
a sensor substrate comprising:
a first pixel and a second pixel that are each configured to sense light of a first wavelength, and
a third pixel and a fourth pixel that are each configured to sense light of a second wavelength; and
a color separating lens array (CSLA) provided on the sensor substrate, the CSLA being configured to separate incident light according to wavelength and condense the separated incident light onto the first pixel, the second pixel, the third pixel, and the fourth pixel,
wherein the first pixel, the second pixel, the third pixel, and the fourth pixel are provided in a 2×2 arrangement,
wherein the first pixel and the second pixel are provided to be oriented diagonal to each other,
wherein the third pixel and the fourth pixel are provided to be oriented diagonal to each other,
wherein the first pixel and the third pixel are provided to be oriented in a first direction with respect to each other,
wherein the first pixel and the fourth pixel are provided to be oriented in a second direction with respect to each other, the second direction being perpendicular to the first direction,
wherein the CSLA comprises a first pixel corresponding region that is provided on the first pixel, a second pixel corresponding region that is provided on the second pixel, a third pixel corresponding region that is provided on the third pixel, and a fourth pixel corresponding region that is provided on the fourth pixel,
wherein each of the first pixel corresponding region, the second pixel corresponding region, the third pixel corresponding region, and the fourth pixel corresponding region comprises a plurality of nanoposts,
wherein the plurality of nanoposts are configured such that color separation occurs only within the 2×2 arrangement, and
wherein the light of the first wavelength and the light of the second wavelength have a complementary color relationship.

2. The image sensor of claim 1, wherein the plurality of nanoposts are further configured such that the color separation occurs between pixels adjacent in the second direction among the first pixel, the second pixel, the third pixel, and the fourth pixel.

3. The image sensor of claim 1, wherein the plurality of nanoposts are further configured such that the color separation occurs between pixels adjacent in the first direction and pixels adjacent in the second direction among the first pixel, the second pixel, the third pixel, and the fourth pixel.

4. The image sensor of claim 1, wherein the plurality of nanoposts are arranged asymmetrically with respect to (i) a line extending in the first direction from a center of each of the first pixel corresponding region, the second pixel corresponding region, the third pixel corresponding region, and the fourth pixel corresponding region and (ii) a line extending in the second direction from the center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

5. The image sensor of claim 1, wherein the plurality of nanoposts are arranged asymmetrically with respect to a line extending in the first direction from a center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

6. The image sensor of claim 1, wherein the plurality of nanoposts are arranged symmetrically with respect to a line extending in the second direction from a center of each of the first pixel corresponding region, the second pixel corresponding region, the third pixel corresponding region, and the fourth pixel corresponding region within each of the first pixel corresponding region, the second pixel corresponding region, the third pixel corresponding region, and the fourth pixel corresponding region.

7. The image sensor of claim 1, wherein the light of the first wavelength is red light, and the light of the second wavelength is cyan light.

8. The image sensor of claim 1, wherein the light of the first wavelength is green light, and the light of the second wavelength is magenta light.

9. The image sensor of claim 1, wherein the light of the first wavelength is blue light, and the light of the second wavelength is yellow light.

10. The image sensor of claim 1,
wherein the sensor substrate further comprises:
a fifth pixel and a sixth pixel that are each configured to sense light of a third wavelength,
a seventh pixel and an eighth pixel that are each configured to sense light of a fourth wavelength,
a ninth pixel and a tenth pixel that are each configured to sense light of a fifth wavelength,
an eleventh pixel and a twelfth pixel that are each configured to sense light of a sixth wavelength,
a thirteenth pixel and a fourteenth pixel that are each configured to sense the light of the first wavelength, and
a fifteenth pixel and a sixteenth pixel that are each configured to sense the light of the second wavelength,
wherein the fifth pixel, the sixth pixel, the seventh pixel, and the eighth pixel are provided in the 2×2 arrangement,
wherein the fifth pixel and the sixth pixel are provided are provided to be oriented diagonal to each other,
wherein the seventh pixel and the eighth pixel are provided to be oriented diagonal to each other,
wherein the fifth pixel and the seventh pixel are provided to be oriented in the first direction with respect to each other,
wherein the fifth pixel and the eighth pixel are provided to be oriented in the second direction with respect to each other,
wherein the ninth pixel, the tenth pixel, the eleventh pixel, and the twelfth pixel are provided in the 2×2 arrangement,
wherein the ninth pixel and the tenth pixel are provided to be oriented diagonal to each other,
wherein the eleventh pixel and the twelfth pixel are provided to be oriented diagonal to each other,
wherein the ninth pixel and the eleventh pixel are provided to be oriented in the first direction with respect to each other,
wherein the ninth pixel and the twelfth pixel are provided to be oriented in the second direction with respect to each other,
wherein the thirteenth pixel, the fourteenth pixel, the fifteenth pixel, and the sixteenth pixel are provided in the 2×2 arrangement,
wherein the thirteenth pixel and the fourteenth pixel are provided to be oriented diagonal to each other,
wherein the fifteen pixel and the sixteenth pixels are provided to be oriented diagonal to each other,
wherein the thirteenth pixel and the fifteenth pixel are provided to be oriented in the first direction with respect to each other,
wherein the thirteenth pixel and the sixteenth pixel are provided to be oriented in the second direction with respect to each other, and
wherein the first pixel, the second pixel, the third pixel, the fourth pixel, the fifth pixel, the sixth pixel, the seventh pixel, the eighth pixel, the ninth pixel, the tenth pixel, the eleventh pixel, the twelfth pixel, the thirteenth pixel, the fourteenth pixel, the fifteenth pixel, and the sixteenth pixel are provided in a 4×4 arrangement.

11. The image sensor of claim 10, wherein the light of the first wavelength is green light, the light of the second wavelength is magenta light, the light of the third wavelength is red light, the light of the fourth wavelength is cyan light, the light of the fifth wavelength is blue light, and the light of the sixth wavelength is yellow light.

12. The image sensor of claim 1, further comprising: a flat lens surrounding the first pixel, the second pixel, the third pixel, and the fourth pixel in the 2×2 arrangement on the CSLA.

13. The image sensor of claim 1, wherein at least one of the first pixel, the second pixel, the third pixel, or the fourth pixel comprises a plurality of sub-pixels.

14. The image sensor of claim 13, wherein the plurality of sub-pixels are configured to be used for autofocusing.

15. An electronic apparatus comprising:
a lens assembly comprising one or more lenses, the lens assembly being configured to form an optical image of a subject;
an image sensor configured to generate an electrical signal based on the optical image formed by the lens assembly; and
a processor configured to process the electrical signal generated by the image sensor,
wherein the image sensor comprises
a sensor substrate comprising:
a first pixel and a second pixel that are each configured to sense light of a first wavelength, and
a third pixel and a fourth pixel that are each configured to sense light of a second wavelength; and
a color separating lens array (CSLA) provided on the sensor substrate, the CSLA being configured to separate incident light according to wavelength and condense the separated incident light onto the first pixel, the second pixel, the third pixel, and the fourth pixel,
wherein the first pixel, the second pixel, the third pixel, and the fourth pixel are provided in a 2×2 arrangement,
wherein the first pixel and the second pixel are provided to be oriented diagonal to each other,
wherein the third pixel and the fourth pixel are provided to be oriented diagonal to each other,
wherein the first pixel and the third pixel are provided to be oriented in a first direction with respect to each other,
wherein the first pixel and the fourth pixel are provided to be oriented in a second direction with respect to each other, the second direction being perpendicular to the first direction,
wherein the CSLA comprises a first pixel corresponding region that is provided on the first pixel, a second pixel corresponding region that is provided on the second pixel, a third pixel corresponding region that is provided on the third pixel, and a fourth pixel corresponding region that is provided on the fourth pixel,
wherein each of the first pixel corresponding region, the second pixel corresponding region, the third pixel corresponding region, and the fourth pixel corresponding region comprises a plurality of nanoposts,
wherein the plurality of nanoposts are configured such that color separation occurs only within the 2×2 arrangement, and
wherein the light of the first wavelength and the light of the second wavelength have a complementary color relationship.

16. The electronic apparatus of claim 15, wherein the plurality of nanoposts are further configured such that the color separation occurs between pixels adjacent in the second direction among the first pixel, the second pixel, the third pixel, and the fourth pixel.

17. The electronic apparatus of claim 15, wherein the plurality of nanoposts are further configured such that the color separation occurs between pixels adjacent in the first direction and pixels adjacent in the second direction among the first pixel, the second pixel, the third pixel, and the fourth pixel.

18. The electronic device of claim 15,
wherein the sensor substrate further comprises:
a fifth pixel and a sixth pixel that are each configured to sense light of a third wavelength,
a seventh pixel and an eighth pixel that are each configured to sense light of a fourth wavelength,
a ninth pixel and a tenth pixel that are each configured to sense light of a fifth wavelength,
an eleventh pixel and a twelfth pixel that are each configured to sense light of a sixth wavelength,
a thirteenth pixel and a fourteenth pixel that are each configured to sense the light of the first wavelength, and
a fifteenth pixel and a sixteenth pixel that are each configured to sense the light of the second wavelength,
wherein the fifth pixel, the sixth pixel, the seventh pixel, and the eighth pixel are provided in the 2×2 arrangement,
wherein the fifth pixel and the sixth pixel are provided are provided to be oriented diagonal to each other,
wherein the seventh pixel and the eighth pixel are provided to be oriented diagonal to each other,
wherein the fifth pixel and the seventh pixel are provided to be oriented in the first direction with respect to each other,
wherein the fifth pixel and the eighth pixel are provided to be oriented in the second direction with respect to each other,
wherein the ninth pixel, the tenth pixel, the eleventh pixel, and the twelfth pixel are provided in the 2×2 arrangement,
wherein the ninth pixel and the tenth pixel are provided to be oriented diagonal to each other,
wherein the eleventh pixel and the twelfth pixel are provided to be oriented diagonal to each other,
wherein the ninth pixel and the eleventh pixel are provided to be oriented in the first direction with respect to each other,
wherein the ninth pixel and the twelfth pixel are provided to be oriented in the second direction with respect to each other,
wherein the thirteenth pixel, the fourteenth pixel, the fifteenth pixel, and the sixteenth pixel are provided in the 2×2 arrangement,
wherein the thirteenth pixel and the fourteenth pixel are provided to be oriented diagonal to each other,
wherein the fifteen pixel and the sixteenth pixels are provided to be oriented diagonal to each other,
wherein the thirteenth pixel and the fifteenth pixel are provided to be oriented in the first direction with respect to each other,
wherein the thirteenth pixel and the sixteenth pixel are provided to be oriented in the second direction with respect to each other, and
wherein the first pixel, the second pixel, the third pixel, the fourth pixel, the fifth pixel, the sixth pixel, the seventh pixel, the eighth pixel, the ninth pixel, the tenth pixel, the eleventh pixel, the twelfth pixel, the thirteenth pixel, the fourteenth pixel, the fifteenth pixel, and the sixteenth pixel are provided in a 4×4 arrangement.

19. The electronic device of claim 18, wherein the light of the first wavelength is green light, the light of the second wavelength is magenta light, the light of the third wavelength is red light, the light of the fourth wavelength is cyan light, the light of the fifth wavelength is blue light, and the light of the sixth wavelength is yellow light.

20. The electronic device of claim 15,
wherein at least one of the first pixel, the second pixel, the third pixel, or the fourth pixel includes a plurality of sub-pixels, and
wherein the plurality of sub-pixels are configured to be used for autofocusing.
